(19) United States
(12) Patent Application Publication
(10) Pub. No.: US 2024/0088276 A1
(43) Pub. Date: Mar. 14, 2024

(54) SEMICONDUCTOR APPARATUS AND METHOD FOR MANUFACTURING SEMICONDUCTOR APPARATUS

(71) Applicant: FUJI ELECTRIC CO., LTD., Kanagawa (JP)

(72) Inventor: Kenichi IGUCHI, Matsumoto-city (JP)

(21) Appl. No.: 18/518,568

(22) Filed: Nov. 23, 2023

Related U.S. Application Data
(63) Continuation of application No. PCT/JP2022/025688, filed on Jun. 28, 2022.

(30) Foreign Application Priority Data
Dec. 8, 2021 (JP) 2021-199175

(51) Int. Cl. H01L 29/739; H01L 29/417; H01L 29/66

(52) U.S. Cl. CPC H01L 29/7397; H01L 29/41708; H01L 29/66348

(57) ABSTRACT

Provided is a semiconductor apparatus having a MOS gate structure, comprising: a semiconductor substrate; a first interlayer dielectric film provided above an upper surface of the semiconductor substrate and including a first opening; and a second interlayer dielectric film stacked on the first interlayer dielectric film and including a second opening overlapping the first opening in a top view, wherein a width of the first opening in a first direction is different from a width of the second opening in the first direction, at a boundary height between the first interlayer dielectric film and the second interlayer dielectric film.

The contents of the following patent application(s) are incorporated herein by reference:
NO. 2021-199175 filed in JP on Dec. 8, 2021
NO. PCT/JP2022/025688 filed in WO on Jun. 28, 2022

### BACKGROUND

### 1. Technical Field

The present invention relates to a semiconductor apparatus and a method for manufacturing the semiconductor apparatus.

### 2. Related Art

Conventionally, a configuration is known in which a contact portion is formed in a mesa portion, in a semiconductor apparatus in which MOS gate structures with a trench gate structure are formed at desired intervals at a surface of the semiconductor substrate, an upper electrode is formed, and furthermore a pattern and an electrode of a desired conductivity type are formed on a back surface side. As for the formation of the contact portion, configurations are known in which an ion is implanted into the mesa portion to form a contact region (see Patent Document 1, for example) and in which a contact metal layer is formed in the mesa portion (see Patent Document 2, for example).
Patent Document 1: WO No. 2016-133027
Patent Document 2: Japanese Patent Application Publication No. 2007-35841

### BRIEF DESCRIPTION OF THE DRAWINGS

FIG. 1 is a top view showing an example of a semiconductor apparatus 100.

FIG. 2 shows a comparative example of a region D in FIG. 1.

FIG. 3 shows an example of a cross section g-g in FIG. 2.

FIG. 4 shows an example of a cross section a-a in FIG. 2.

FIG. 5 shows an example of a cross section b-b in FIG. 2.

FIG. 6 shows a perspective view of a semiconductor substrate 10 of the semiconductor apparatus 100 in FIG. 2.

FIG. 7 shows another example of a cross section g-g in FIG. 2.

FIG. 8 shows another example of the cross section g-g in FIG. 2.

FIG. 9 shows an exemplary embodiment of the region D in FIG. 1.

FIG. 10 shows an example of a cross section h-h in FIG. 9.

FIG. 11 shows another example of the cross section h-h in FIG. 9.

FIG. 12 shows another example of the cross section h-h in FIG. 9.

FIG. 13 shows another example of the cross section h-h in FIG. 9.

FIG. 14 shows another example of the cross section h-h in FIG. 9.

FIG. 15 shows another example of the cross section h-h in FIG. 9.

FIG. 16 shows another example of the cross section h-h in FIG. 9.

FIG. 17 shows another example of the cross section h-h in FIG. 9.

FIG. 18 shows another exemplary embodiment of the region D in FIG. 1.

FIG. 19 shows an example of a cross section i-i in FIG. 18.

FIG. 20 shows a perspective view of the semiconductor apparatus 100 in FIG. 18.

FIG. 21 shows another example of the cross section i-i in FIG. 18.

FIG. 22 shows another example of the cross section i-i in FIG. 18.

FIG. 23 shows another exemplary embodiment of the region D in FIG. 1.

FIG. 24 shows an example of a cross section j-j in FIG. 23.

FIG. 25 illustrates an example of a flowchart of a method for manufacturing the semiconductor apparatus 100 shown in FIG. 15.

FIG. 26 shows an example of a gate trench portion formation step S101.

FIG. 27 shows an example of a first interlayer dielectric film formation step S102.

FIG. 28 shows an example of a first opening formation step S103.

FIG. 29 shows an example of a first contact portion formation step S104.

FIG. 30 shows an example of a second interlayer dielectric film formation step S105.

FIG. 31 shows an example of a second opening formation step S106.

FIG. 32 shows an example of a second contact portion formation step S107.

FIG. 33 shows an example of an emitter electrode formation step S108.

FIG. 34 shows details of the semiconductor apparatus 100 shown in FIG. 10.

FIG. 35 shows another exemplary embodiment of the region D in FIG. 1.

FIG. 36 shows an example of a cross section k-k in FIG. 35.

FIG. 37 shows another exemplary embodiment of the region D in FIG. 1.

FIG. 38 shows another exemplary embodiment of the region D in FIG. 1.

FIG. 39 shows another exemplary embodiment of the region D in FIG. 1.

FIG. 40 shows another exemplary structure of a first segment 54-1-1 of a contact hole 54-1 and a first segment 62-1-1 of a plug metal 62-1.

FIG. 41 shows another exemplary structure of the first segment 54-1-1 of the contact hole 54-1 and the first segment 62-1-1 of the plug metal 62-1.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to solutions of the invention.

In the present specification, one side in a direction parallel to a depth direction of a semiconductor substrate is referred to as “upper” and the other side is referred to as “lower”. One surface of two principal surfaces of a substrate, a layer or other members is referred to as an upper surface, and the other surface is referred to as a lower surface. The ‘upper’ and ‘lower’ directions are not limited to a gravity direction or a direction at a time of mounting a semiconductor apparatus.

In the present specification, technical matters may be described using orthogonal coordinate axes of an X axis, a Y axis, and a Z axis. The orthogonal coordinate axes are merely for specifying relative positions of components, and not for limiting a specific direction. For example, the Z axis is not limited to indicate a height direction with respect to the ground. It should be noted that a +Z axis direction and a −Z axis direction are directions opposite to each other. When a Z axis direction is described without describing a positive or negative sign, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In addition, a region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor that supplies electrons. In the present specification, the VOH defect may be referred to as a hydrogen donor.

In the present specification, a description of a P+ type or an N+ type means a higher doping concentration than that of the P type or the N type, and a description of a P− type or an N− type means a lower doping concentration than that of the P type or the N type. In the present specification, a unit system is the SI base unit system unless otherwise particularly noted. Although a unit of length is represented using cm, it may be converted to meters (m) before calculations.

A chemical concentration in the present specification refers to an atomic density of an impurity measured regardless of an electrical activation state. The chemical concentration (atomic density) can be measured by, for example, secondary ion mass spectrometry (SIMS). The net doping concentration described above can be measured by voltage-capacitance profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

In addition, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300K (Kelvin) (about 26.9 degrees C.) may be used for the value at the room temperature.

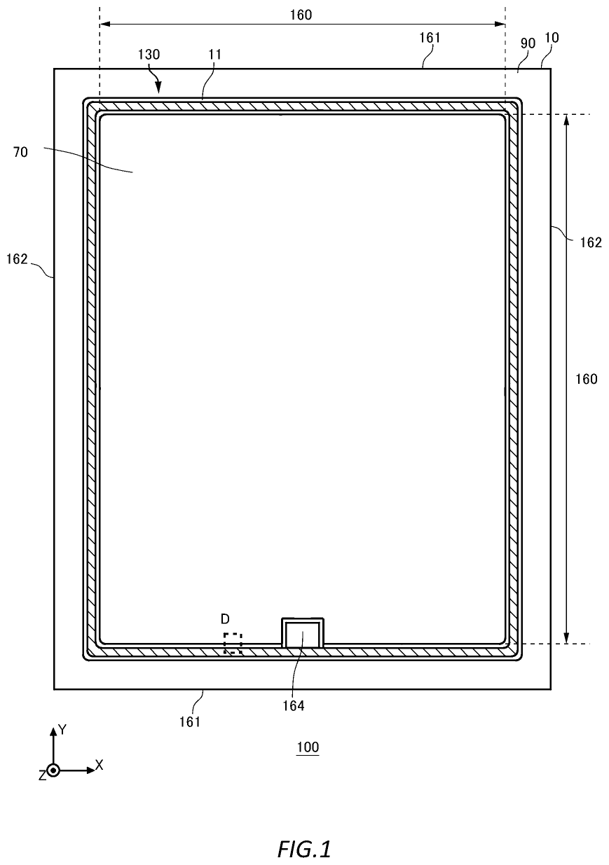

FIG. 1 is a top view showing an example of a semiconductor apparatus 100. FIG. 1 shows a position of each member projected onto an upper surface of a semiconductor substrate 10. In FIG. 1, only some members of the semiconductor apparatus 100 are shown, and some members are omitted.

The semiconductor apparatus 100 includes the semiconductor substrate 10. The semiconductor substrate 10 is a substrate formed of a semiconductor material. The semiconductor substrate 10 is a silicon substrate, as an example, but a material of the semiconductor substrate 10 is not limited to silicon.

The semiconductor substrate 10 has a first end side 161 and a second end side 162 in a top view. When merely referred to as the top view in the present specification, it means that the semiconductor substrate 10 is viewed from an upper surface side. The semiconductor substrate 10 in the present example has one set of first end sides 161 facing each other in a top view. In addition, the semiconductor substrate 10 in the present example has one set of second end sides 162 facing each other in a top view. In FIG. 1, the first end side 161 is parallel to the X axis direction. The second end side 162 is parallel to the Y axis direction. In addition, the Z axis is perpendicular to the upper surface of the semiconductor substrate 10. In addition, the first end side 161 is perpendicular to an extending direction of a gate trench portion to be described later. The second end side 162 is parallel to the extending direction of the gate trench portion to be described later.

The semiconductor substrate 10 is provided with an active portion 160. The active portion 160 is a region where a main current flows in the depth direction between the upper surface and a lower surface of the semiconductor substrate 10 when the semiconductor apparatus 100 operates. An emitter electrode is provided above the active portion 160, but is omitted in FIG. 1.

In the present example, the active portion 160 is provided with a transistor portion 70 including a transistor element such as an Insulated Gate Bipolar Transistor (IGBT). In another example, transistor portions 70 and diode portions including diode elements such as a Free Wheel Diode (FWD) may be alternately arranged along a predetermined direction at the upper surface of the semiconductor substrate 10. One transistor portion 70 is provided in the present example, but a plurality of transistor portions 70 may be provided. A well region of the P+ type, or a gate runner to be described later may be provided between the plurality of transistor portions 70.

The transistor portion 70 has a collector region of the P+ type in a region in contact with the lower surface of the semiconductor substrate 10. In addition, in the transistor portion 70, MOS gate structures having emitter regions of the N+ type, base regions of the P− type, gate conductive portions, and gate dielectric films are periodically arranged on the upper surface side of the semiconductor substrate 10. That is, the semiconductor apparatus 100 in the present example has a MOS gate structure.

The semiconductor apparatus 100 may have one or more pads above the semiconductor substrate 10. The semiconductor apparatus 100 in the present example has a gate pad 164. The semiconductor apparatus 100 may have pads such as an anode pad, a cathode pad, and a current detection pad. Each pad may be arranged in the vicinity of the first end side 161. The vicinity of the first end side 161 refers to a region between the first end side 161 in a top view and the emitter electrode. When the semiconductor apparatus 100 is mounted, each pad may be connected to an external circuit via a wiring line such as a wire.

A gate potential is applied to the gate pad 164. The gate pad 164 is electrically connected to a conductive portion of the gate trench portion of the active portion 160. The semiconductor apparatus 100 includes a gate wiring line 130 that connects the gate pad 164 and the gate trench portion. In FIG. 1, the gate wiring line 130 is hatched with diagonal lines.

The gate wiring line 130 is arranged between the active portion 160 and the first end side 161 or the second end side 162 in a top view. The gate wiring line 130 in the present example encloses the active portion 160 in a top view. A region enclosed by the gate wiring line 130 in a top view may be the active portion 160. In addition, the gate wiring line 130 is connected to the gate pad 164. The gate wiring line 130 is arranged above the semiconductor substrate 10. The gate wiring line 130 may be a metal wiring line containing aluminum or the like.

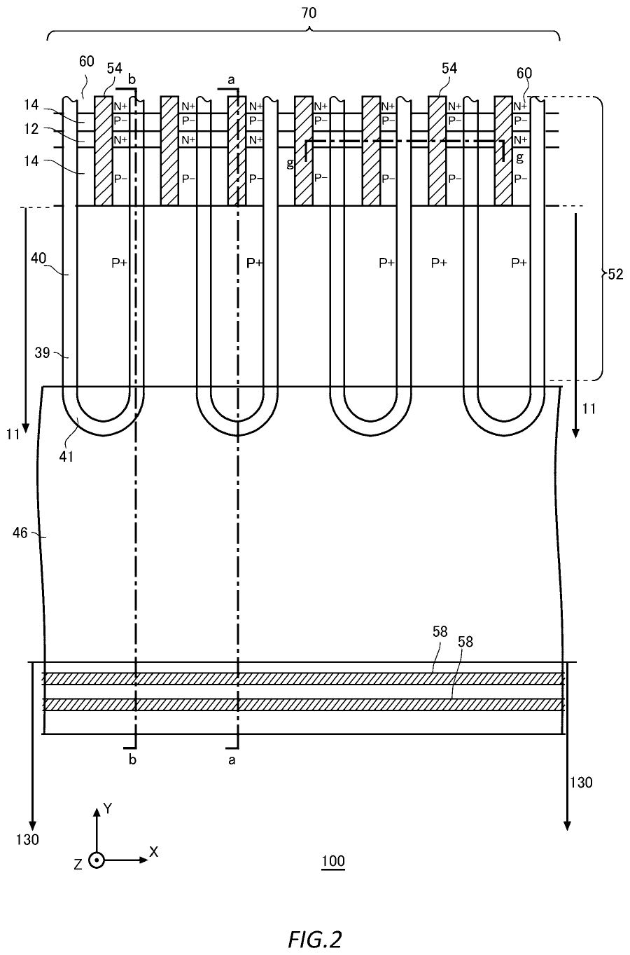

An outer circumferential well region 11 is provided to overlap the gate wiring line 130. That is, like the gate wiring line 130, the outer circumferential well region 11 encloses the active portion 160 in a top view. The outer circumferential well region 11 is also provided extending with a predetermined width in a range which does not overlap the gate wiring line 130. The outer circumferential well region 11 is a region of a second conductivity type. The outer circumferential well region 11 in the present example is of the P+ type (see FIG. 2). An impurity concentration of the outer circumferential well region 11 may be 5.0×10¹⁷ atoms/cm³ or more and 5.0×10¹⁹ atoms/cm³ or less. The impurity concentration of the outer circumferential well region 11 may be 2.0×10¹⁸ atoms/cm³ or more and 2.0×10¹⁹ atoms/cm³ or less.

In addition, the semiconductor apparatus 100 may include a temperature sensing portion (not shown) which is a PN junction diode formed of polysilicon or the like, and a current detection portion (not shown) which simulates operation of the transistor portion 70 provided in the active portion 160. The temperature sensing portion may be connected to the anode pad and the cathode pad via the wiring line. When the temperature sensing portion is provided, the temperature sensing portion is preferably provided at a center of the semiconductor substrate 10 in the X axis direction and the Y axis direction.

The semiconductor apparatus 100 in the present example includes an edge termination structure portion 90 between the active portion 160 and the first end side 161 or the second end side 162 in a top view. The edge termination structure portion 90 in the present example is arranged between the outer circumferential gate wiring line 130 and the first end side 161 or the second end side 162. The edge termination structure portion 90 reduces electric field strength on the upper surface side of the semiconductor substrate 10. The edge termination structure portion 90 may include at least one of a guard ring, a field plate, or a RESURF which is annularly provided enclosing the active portion 160. Furthermore, the semiconductor apparatus 100 may be used as a reverse blocking IGBT by providing a region of the p type on the entire side wall of the semiconductor substrate 10 and connecting this to the collector region of the IGBT.

FIG. 2 shows a comparative example of a region D in FIG. 1. FIG. 2 is an enlarged view of the region D in FIG. 1. The region D is a region including the transistor portion 70 in the vicinity of the gate wiring line 130. The semiconductor apparatus 100 in the present example includes a gate trench portion 40, the outer circumferential well region 11, an emitter region 12, and a base region 14 which are provided in an interior portion on an upper surface side of the semiconductor substrate 10.

The semiconductor apparatus 100 in the present example includes an emitter electrode 52 and the gate wiring line 130 which are provided above an upper surface of the semiconductor substrate 10. The emitter electrode 52 and the gate wiring line 130 are provided separately from each other. In addition, an interlayer dielectric film is provided between the emitter electrode 52 and the gate wiring line 130, and the upper surface of the semiconductor substrate 10. In FIG. 2, the interlayer dielectric film is omitted.

The emitter electrode 52 is provided above the gate trench portion 40, the outer circumferential well region 11, the emitter region 12, and the base region 14.

The emitter electrode 52 is in contact with the emitter region 12 and the base region 14 at the upper surface of the semiconductor substrate 10 through a contact hole 54. It should be noted that FIG. 2 shows a shape of the contact hole 54 at the upper surface of the semiconductor substrate 10.

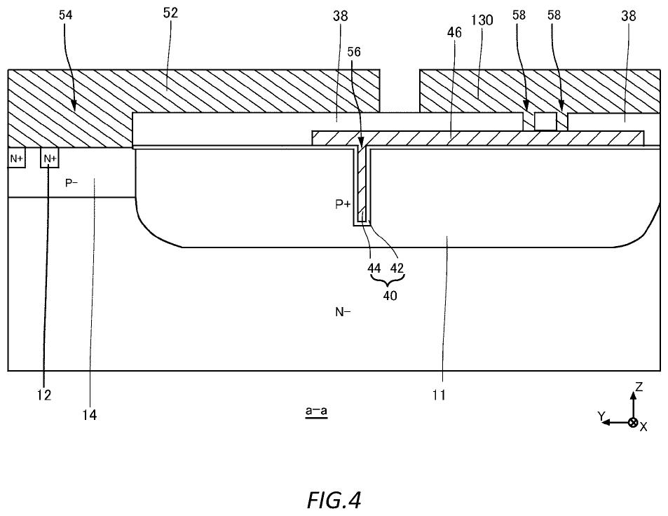

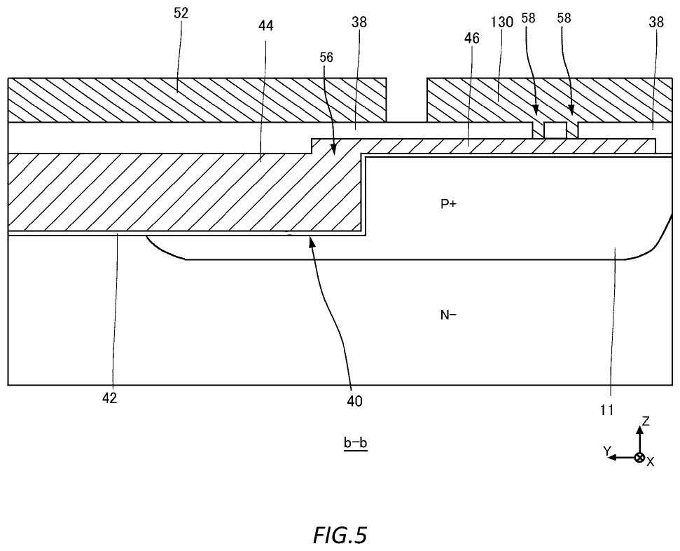

The gate wiring line 130 is connected to a gate runner 46 through a contact hole 58 provided in the interlayer dielectric film. The gate runner 46 is connected to the gate trench portion 40. That is, the gate wiring line 130 is connected to the gate trench portion 40 via the gate runner 46. The gate runner 46 is connected to a gate conductive portion of the gate trench portion 40 through a contact hole 56 (see FIG. 4 and FIG. 5) provided in the interlayer dielectric film. The contact hole 56 may be provided in a range where the gate conductive portion of the gate trench portion 40 overlaps the gate runner 46. The gate wiring line 130 may be connected to the gate conductive portion of the gate trench portion 40 at an edge portion 41 of the gate trench portion 40 in the Y axis direction. The gate runner 46 is formed of polysilicon which is a conductive material. The gate runner 46 may be provided above the semiconductor substrate 10. The gate runner 46 is provided along a direction in which the gate wiring line 130 extends (the X axis direction in FIG. 2).

The emitter electrode 52 is formed of a material containing metal. For example, at least partial region of the emitter electrode 52 is formed of aluminum or an aluminum-silicon alloy, for example, a metal alloy such as AlSi, AlSiCu.

The transistor portion 70 has a plurality of gate trench portions 40 arrayed in an array direction. The array direction in FIG. 2 is the X axis direction. The array direction is an example of a first direction. In the present example, the gate trench portion 40 is provided in the active portion 160 and the outer circumferential well region 11 at the upper surface of the semiconductor substrate 10. The gate trench portions 40 are provided in stripes in a top view in the transistor portion 70.

The gate trench portion 40 in the present example may have two linear segments 39 extending along an extending direction perpendicular to the array direction (trench segments which are linear along the extending direction), and the edge portion 41 connecting the two linear segments 39. The extending direction in FIG. 2 is the Y axis direction.

At least part of the edge portion 41 is preferably provided in a curved shape in a top view. The edge portion 41 connects end portions of the two linear segments 39 in the Y axis direction, so that electric field strength at the end portions of the linear segments 39 can be reduced.

A dummy trench portion may be provided between respective linear segments 39 of the gate trench portion 40. The dummy trench portion may have a linear segment. A conductive portion of the dummy trench portion may be connected to the emitter electrode 52.

A diffusion depth of the outer circumferential well region 11 may be deeper than a depth of the gate trench portion 40. An end portion of the gate trench portion 40 in the Y axis direction is provided in the outer circumferential well region 11 in a top view. That is, at the end portion of the gate trench portion 40 in the Y axis direction, a bottom portion of the gate trench portion 40 in the depth direction is covered with the outer circumferential well region 11. This can reduce electric field strength at the bottom portion of the gate trench portion 40. In addition, the semiconductor apparatus 100 may include the gate trench portion 40 which is entirely provided in the outer circumferential well region 11 in a top view.

In the array direction, a mesa portion is provided between the gate trench portions 40. The mesa portion refers to a region sandwiched between the trench portions in the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided extending in the extending direction (the Y axis direction) along the trench portion, at the upper surface of the semiconductor substrate 10. In the present example, a mesa portion 60 is provided in the transistor portion 70.

Each mesa portion 60 may be provided with at least one of the emitter region 12 of a first conductivity type or the base region 14 of a second conductivity type. The emitter region 12 in the present example is of the N+ type, and the base region 14 is of the P− type. The emitter region 12 may be provided between the base region 14 and the upper surface of the semiconductor substrate 10 in the depth direction.

The mesa portion 60 of the transistor portion 70 includes the emitter region 12 exposed on the upper surface of the semiconductor substrate 10. The emitter region 12 is provided in contact with the gate trench portion 40. The mesa portion 60 in contact with the gate trench portion 40 may be provided with the base region 14 exposed on the upper surface of the semiconductor substrate 10. In the present example, a region exposed on the upper surface of the semiconductor substrate 10 in the mesa portion 60 and arranged closest to the gate wiring line 130 is the base region 14.

Base regions 14 and emitter regions 12 in the mesa portion 60 are each provided from one gate trench portion 40 to the other gate trench portion 40 in the array direction, at an upper surface 21 of the semiconductor substrate 10. As an example, the base regions 14 and the emitter regions 12 of the mesa portion 60 are alternately arranged along the extending direction of the trench portion (the Y axis direction). It should be noted that a region sandwiched between the emitter regions 12 in the extending direction may be provided with a contact region of the P+ type instead of the base region 14.

In another example, the base regions 14 and the emitter regions 12 of the mesa portion 60 may be provided in stripes along the extending direction of the gate trench portion 40, at the upper surface 21 of the semiconductor substrate 10. For example, the emitter region 12 is provided in a region in contact with the gate trench portion 40, and the base region 14 is provided in a region sandwiched between the emitter regions 12 in the array direction.

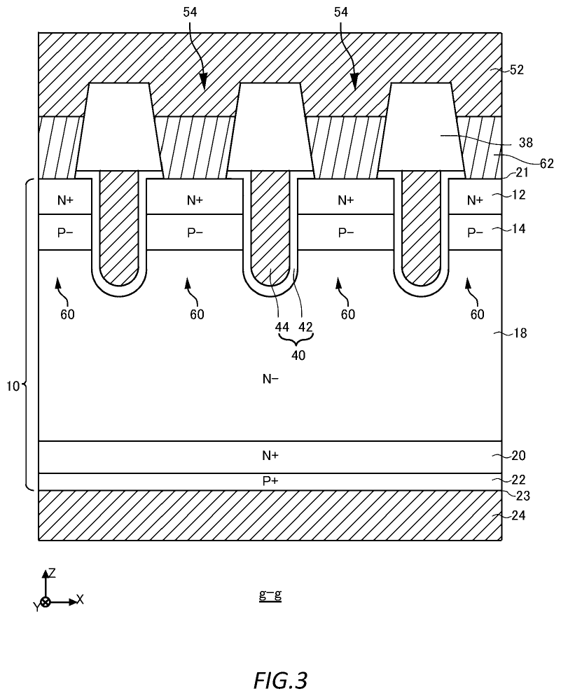

FIG. 3 shows an example of a cross section g-g in FIG. 2. The cross section g-g is an XZ plane passing through the emitter region 12. It should be noted that the dimensions in FIG. 3 do not necessarily match the dimensions in FIG. 2. The semiconductor apparatus 100 in the present example includes the semiconductor substrate 10, the interlayer dielectric film 38, the emitter electrode 52, and the collector electrode 24 in the cross section.

The interlayer dielectric film 38 is provided on the upper surface 21 of the semiconductor substrate 10. The interlayer dielectric film 38 is a film including at least one of a dielectric film such as silicate glass to which an impurity such as boron or phosphorus is added, a thermal oxide film, or other dielectric films. The interlayer dielectric film 38 is provided with the contact hole 54 described in FIG. 2.

The emitter electrode 52 is provided above the interlayer dielectric film 38. The emitter electrode 52 is in contact with the upper surface 21 of the semiconductor substrate 10 via a plug metal 62 provided in the contact hole 54 of the interlayer dielectric film 38. It should be noted that the emitter electrode 52 may be provided above the outer circumferential well region 11. The gate wiring line 130 may be provided above the outer circumferential well region 11. In the present example, the gate runner 46 is provided below the gate wiring line 130.

The contact hole 54 is provided with the plug metal 62. The plug metal 62 electrically connects the semiconductor substrate 10 and the emitter electrode 52. Providing the plug metal 62 can reduce a contact resistance between the semiconductor substrate 10 and the emitter electrode 52. The plug metal 62 is formed of Ta, W, Mo, or the like, as an example. The plug metal 62 is an example of a contact portion.

The collector electrode 24 is provided on a lower surface 23 of the semiconductor substrate 10. The emitter electrode 52 and the collector electrode 24 are formed of a metal material such as aluminum or nickel. In addition, a conductive material other than metal may be used. In the present specification, the direction (Z axis direction) connecting the emitter electrode 52 and the collector electrode 24 is referred to as the depth direction or the height direction.

The semiconductor substrate 10 includes a drift region 18 of a first conductivity type. The drift region 18 in the present example is of the N− type.

In the mesa portion 60, the emitter region 12 of the N+ type and the base region 14 of the P− type are provided in this order from an upper surface 21 side of the semiconductor substrate 10. The drift region 18 is provided below the base region 14. In addition, the mesa portion 60 may be provided with an accumulation region of the N+ type (not shown).

The emitter region 12 is exposed on the upper surface 21 of the semiconductor substrate 10, and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in the present example is provided in contact with the emitter region 12. The base region 14 may be in contact with the trench portions on both sides of the mesa portion 60. A peak of an impurity concentration of the base region 14 is 2.5×10¹⁷ atoms/cm³, as an example. The impurity concentration of the base region 14 may be 5.0×10¹⁶ atoms/cm³ or more and 1.0×10¹⁸ atoms/cm³ or less.

A buffer region 20 of the N+ type may be provided below the drift region 18. A doping concentration of the buffer region 20 is higher than a doping concentration of the drift region 18. The buffer region 20 may have a concentration peak having a higher doping concentration than the drift region 18. The doping concentration of the concentration peak refers to a doping concentration at a local maximum of the concentration peak. In addition, as the doping concentration of the drift region 18, an average value of doping concentrations in a region where the doping concentration distribution is substantially flat may be used.

The buffer region 20 may be formed through ion implantation of the dopant of the N type such as hydrogen (proton) or phosphorus. The buffer region 20 in the present example is formed through the ion implantation of hydrogen. The buffer region 20 may function as a field stop layer which prevents a depletion layer expanding from a lower end of the base region 14 from reaching a collector region 22 of the P+ type.

The collector region 22 of the P+ type is provided under the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron. The element serving as the acceptor is not limited to the example described above.

The collector region 22 is exposed on the lower surface 23 of the semiconductor substrate 10, and is connected to the collector electrode 24. The collector electrode 24 may be in contact with the entire lower surface 23 of the semiconductor substrate 10. The emitter electrode 52 and the collector electrode 24 are formed of a metal material such as aluminum or nickel.

One or more gate trench portions 40 are provided on the upper surface 21 side of the semiconductor substrate 10. In the present example, a plurality of gate trench portions 40 are provided on the upper surface 21 side of the semiconductor substrate 10. The gate trench portion 40 is provided from the upper surface 21 of the semiconductor substrate 10 to an inside of the semiconductor substrate 10. The gate trench portion 40 extends from the upper surface 21 of the semiconductor substrate 10 through the base region 14, to reach the drift region 18. In a region where at least one of the emitter region 12 or the base region 14 is provided, each of the gate trench portions 40 also extends through these doping regions, to reach the drift region 18. A configuration of the trench portions extending through the doping regions is not limited to what is manufactured in an order of forming the doping regions and then forming the trench portions. The configuration of the trench portions extending through the doping regions also includes a configuration of forming the trench portions and then forming the doping regions between the trench portions.

The gate trench portion 40 includes a gate trench, a gate dielectric film 42, and a gate conductive portion 44 which are provided at the upper surface 21 of the semiconductor substrate 10. The gate conductive portion 44 is formed of polysilicon which is a conductive material. The gate conductive portion 44 may be formed of the same material as that of the gate runner 46. The gate conductive portion 44 is provided on the semiconductor substrate 10. The gate dielectric film 42 is provided covering an inner wall of the gate trench. The gate dielectric film 42 may be formed by oxidizing or nitriding a semiconductor on the inner wall of the gate trench. In FIG. 3, the gate conductive portion 44 is provided farther inward in the gate trench than the gate dielectric film 42. That is, the gate dielectric film 42 insulates the gate conductive portion 44 from the semiconductor substrate 10. A thickness of the gate dielectric film 42 may be 50 nm or more and 150 nm or less.

The gate conductive portion 44 in the gate trench portion 40 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate wiring line 130. When a predetermined gate voltage is applied to the gate conductive portion 44, a channel is formed by an electron inversion layer in a surface layer of the base region 14 at a boundary surface in contact with the gate trench portion 40.

The gate trench portion 40 in the present example is covered by the interlayer dielectric film 38 on the upper surface 21 of the semiconductor substrate 10. It should be noted that a bottom portion of the gate trench portion 40 may have a curved surface (a curved shape in the cross section) protruding downward.

An upper surface of the emitter electrode 52 may be provided with a protective film (not shown). Providing the protective film on the upper surface of the emitter electrode 52 can protect the electrode. The protective film may be provided through patterning. The protective film is a polyimide film, as an example.

FIG. 4 shows an example of a cross section a-a in FIG. 2. The cross section a-a is a YZ plane passing through the contact hole 54 and the contact hole 56. It should be noted that the dimensions in FIG. 4 do not necessarily match the dimensions in FIG. 2. The semiconductor apparatus 100 in the present example includes the semiconductor substrate 10, the interlayer dielectric film 38, the emitter electrode 52, and the collector electrode 24 in the cross section. It should be noted that, in FIG. 4, illustration of the vicinity of the lower surface 23 of the semiconductor substrate 10 is omitted. In the cross section, the upper surface 21 of the semiconductor substrate 10 is connected to the emitter electrode 52 via the contact hole 54. In addition, in the cross section, the gate runner 46 is connected to the gate conductive portion 44 of the gate trench portion 40 via the contact hole 56.

FIG. 5 shows an example of a cross section b-b in FIG. 2. The cross section b-b is a YZ plane passing through the contact hole 56. It should be noted that the dimensions in FIG. 5 do not necessarily match the dimensions in FIG. 2. The semiconductor apparatus 100 in the present example includes the semiconductor substrate 10, the interlayer dielectric film 38, the emitter electrode 52, and the collector electrode 24 in the cross section. It should be noted that, in FIG. 5, illustration of the vicinity of the lower surface 23 of the semiconductor substrate 10 is omitted. In the cross section as well, the gate runner 46 is connected to the gate conductive portion 44 of the gate trench portion 40 via the contact hole 56.

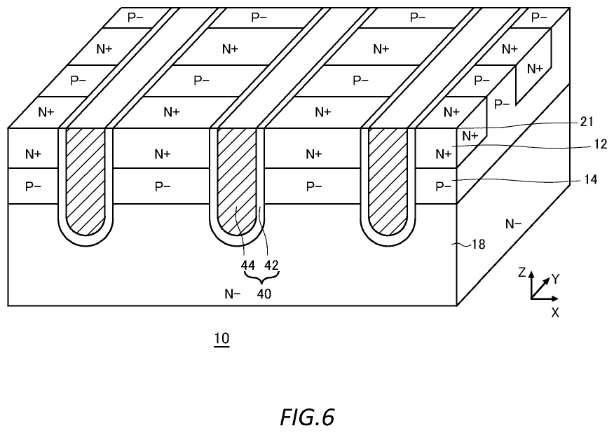

FIG. 6 shows a perspective view of the semiconductor substrate 10 of the semiconductor apparatus 100 in FIG. 2. FIG. 6 shows arrangement of the emitter region 12 and the base region 14 in the semiconductor substrate 10. It should be noted that, in FIG. 6, illustration of the vicinity of the lower surface 23 of the semiconductor substrate 10 is omitted. As shown in FIG. 6, the base regions 14 and the emitter regions 12 are alternately arranged along an extending direction of the gate trench portion 40 (the Y axis direction). In addition, as shown in FIG. 6, the base region 14 is provided below the emitter region 12.

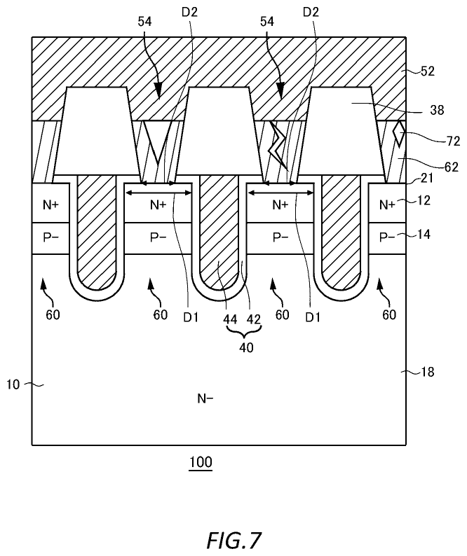

FIG. 7 shows another example of a cross section g-g in FIG. 2. In a cross-sectional view in FIG. 7, a width D1 of the mesa portion 60 is smaller than that in the cross-sectional view in FIG. 3. The width D1 of the mesa portion 60 may be a distance between adjacent gate trench portions 40. It should be noted that, in FIG. 7, illustration of the vicinity of the lower surface 23 of the semiconductor substrate 10 is omitted.

In order to miniaturize the semiconductor apparatus 100, there is a need to reduce not only a width of the gate conductive portion 44 of the gate trench portion 40 but also the width D1 of the mesa portion 60. However, reducing the width D1 of the mesa portion 60 decreases an opening width D2 of the contact hole 54. In FIG. 7, the opening width D2 of the contact hole 54 is a width of the contact hole 54 at the upper surface 21 of the semiconductor substrate 10. Decreasing the opening width D2 of the contact hole makes it difficult to uniformly deposit the plug metal 62, which may cause a formation failure 72. The formation failure 72 causes generation of outgas due to, for example, heating, and becomes a starting point of fracture due to stress, which can cause the semiconductor apparatus 100 to have a characteristic failure.

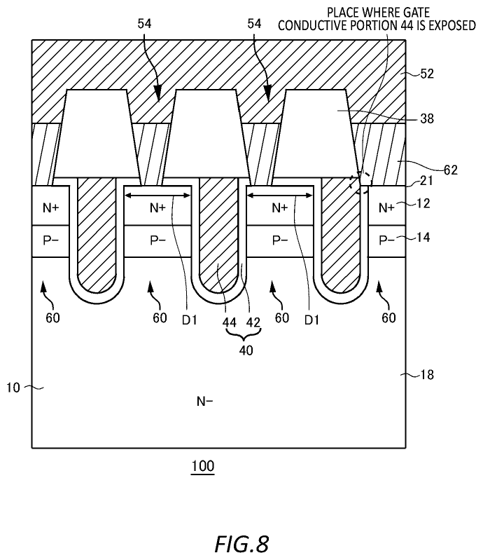

FIG. 8 shows another example of the cross section g-g in FIG. 2. In a cross-sectional view in FIG. 8, the width D1 of the mesa portion 60 is smaller than that in the cross-sectional view in FIG. 3. It should be noted that, in FIG. 8, illustration of the vicinity of the lower surface 23 of the semiconductor substrate 10 is omitted.

Reducing the width D1 of the mesa portion 60 decreases a width of a region which can be in contact with the emitter electrode 52. In order to obtain sufficient contact, it is preferable to match an opening pattern of the contact hole 54 with a pattern of the mesa portion 60 as much as possible. However, the interlayer dielectric film 38 requires a thickness of, for example, 1 μm or more, in order to reliably coat a level difference on a structural object and to ensure an insulation property, a barrier property. When an opening is formed by etching the interlayer dielectric film 38 which is thick, high alignment accuracy is required, and there may be a place generated where the gate conductive portion 44 is exposed as in FIG. 8. In this case, the semiconductor apparatus 100 will have a characteristic failure. In addition, the contact hole 54 must have a forward tapered shape for ion implantation and electrode formation after the contact hole 54 is formed, which makes miniaturization difficult.

In addition, when a diameter of the semiconductor substrate 10 is increased, flatness of a surface of the semiconductor substrate 10 is decreased, and resolution of photolithography varies in the surface of the semiconductor substrate 10. Accordingly, it becomes difficult to provide reliable and uniform electrical contact between the mesa portion 60 and the contact portion, which makes it difficult to form a low-resistance contact portion.

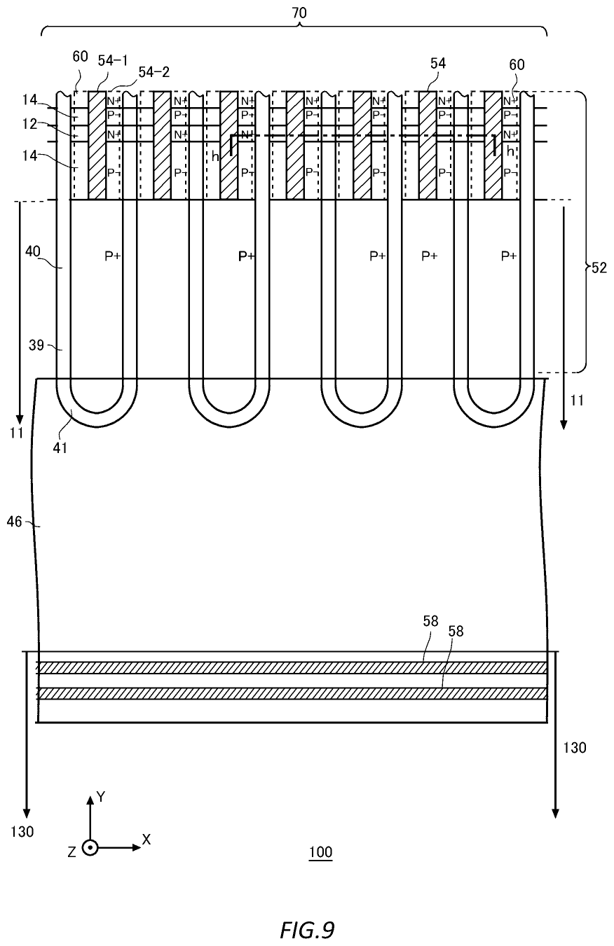

FIG. 9 shows an exemplary embodiment of the region D in FIG. 1. FIG. 9 is an enlarged view of the region D in FIG. 1. The semiconductor apparatus 100 in FIG. 9 is different from the semiconductor apparatus 100 in FIG. 2 in a configuration of the contact hole 54. Except for that, a configuration of the semiconductor apparatus 100 in FIG. 9 may be the same as that of the semiconductor apparatus 100 in FIG. 2. The semiconductor apparatus 100 in FIG. 9 has a contact hole 54-1 and a contact hole 54-2.

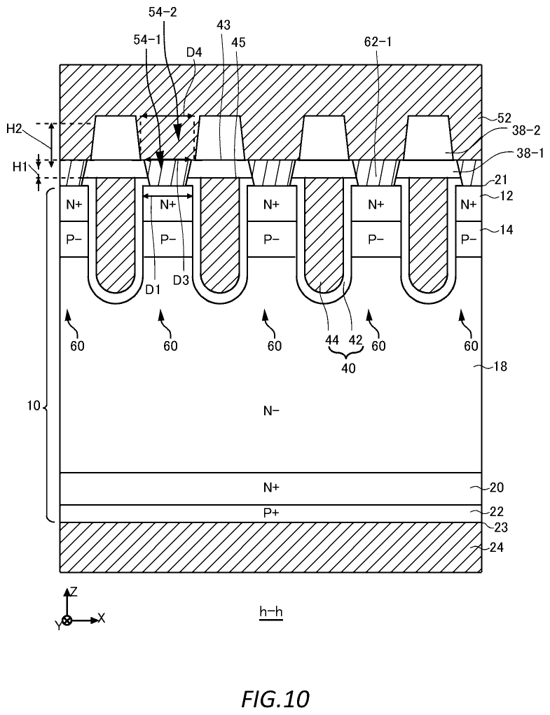

FIG. 10 shows an example of a cross section h-h in FIG. 9. The cross section h-h is an XZ plane passing through the emitter region 12. It should be noted that the dimensions in FIG. 10 do not necessarily match the dimensions in FIG. 9. The semiconductor apparatus 100 in the present example includes the semiconductor substrate 10, the interlayer dielectric film 38, the emitter electrode 52, and the collector electrode 24 in the cross section. The semiconductor apparatus 100 in FIG. 10 is different from the semiconductor apparatus 100 in FIG. 3 in configurations of the contact hole 54 and the interlayer dielectric film 38. Except for that, a configuration of the semiconductor apparatus 100 in FIG. 10 may be the same as that of the semiconductor apparatus 100 in FIG. 3.

In the present example, the semiconductor apparatus 100 includes an interlayer dielectric film 38-1 and an interlayer dielectric film 38-2. The interlayer dielectric film 38-1 is provided above the upper surface 21 of the semiconductor substrate 10. In the present example, the interlayer dielectric film 38-1 is provided on the upper surface 21 of the semiconductor substrate 10. The interlayer dielectric film 38-2 is provided above the upper surface 21 of the semiconductor substrate 10. The interlayer dielectric film 38-1 covers at least part of an upper surface 45 of the gate conductive portion 44. In the cross section, the interlayer dielectric film 38-1 covers the entire upper surface 45 of the gate conductive portion 44. In the present example, the interlayer dielectric film 38-2 is stacked on the interlayer dielectric film 38-1. In FIG. 10, the entire interlayer dielectric film 38-2 is provided on an upper surface 43 of the interlayer dielectric film 38-1. The interlayer dielectric film 38-1 is an example of a first interlayer dielectric film. The interlayer dielectric film 38-2 is an example of a second interlayer dielectric film.

The interlayer dielectric film 38-1 has the contact hole 54-1. The contact hole 54-1 may be provided in the gate dielectric film 42. In addition, the interlayer dielectric film 38-2 has the contact hole 54-2. FIG. 9 shows a shape of the contact hole 54-1 at the upper surface of the semiconductor substrate 10, and a shape of the contact hole 54-2 at a boundary height between the interlayer dielectric film 38-1 and the interlayer dielectric film 38-2. As shown in FIG. 9, the contact hole 54-2 overlaps the contact hole 54-1 in a top view. The contact hole 54-2 may overlap the entire contact hole 54-1. The contact hole 54-1 is an example of a first opening, and the contact hole 54-2 is an example of a second opening.

At least part of a plug metal 62-1 is provided in the contact hole 54-1. In the present example, the entire plug metal 62-1 is provided in the contact hole 54-1. In addition, the plug metal 62-1 is provided in the entire contact hole 54-1. The plug metal 62-1 may be formed of a high-melting point metal material such as Ta, W, or Mo. The plug metal 62-1 is an example of a contact portion. Providing the plug metal 62-1 can reduce a contact resistance between the emitter electrode 52 and the mesa portion 60.

In FIG. 10, a width D3 of the contact hole 54-1 and a width D4 of the contact hole 54-2 in the array direction are different, at the boundary height between the interlayer dielectric film 38-1 and the interlayer dielectric film 38-2. That is, in a top view, a pattern of the contact hole 54-1 at the boundary height is different from a pattern of the contact hole 54-2 at the boundary height. Making the width D3 of the contact hole 54-1 different from the width D4 of the contact hole 54-2 can change a shape of a trench portion in response to miniaturization, and can easily form a low-resistance contact portion.

In the present example, the width D4 of the contact hole 54-2 in the array direction is larger than the width D3 of the contact hole 54-1 in the array direction at the boundary height. That is, in the present example, at least part of the upper surface 43 of the interlayer dielectric film 38-1 is not covered with the interlayer dielectric film 38-2. The width D4 of the contact hole 54-2 may be 1.1 times or more the width D3 of the contact hole 54-1. The width D4 of the contact hole 54-2 may be 1.2 times or more the width D3 of the contact hole 54-1. The width D4 of the contact hole 54-2 may be 1.5 times or more the width D3 of the contact hole 54-1. The width D4 of the contact hole 54-2 may be 3.0 times or less the width D3 of the contact hole 54-1. The width D4 of the contact hole 54-2 may be 2.0 times or less the width D3 of the contact hole 54-1. Making the width D4 of the contact hole 54-2 larger than the width D3 of the contact hole 54-1 allows reliable contact between the contact portion (the plug metal 62-1) and the emitter electrode 52. Accordingly, the low-resistance contact portion can be easily formed.

The width D3 of the contact hole 54-1 at the boundary height may be 0.5 μm or more and 1.5 μm or less. The width D4 of the contact hole 54-2 at the boundary height may be 0.6 μm or more and 2.0 μm or less.

A thickness H1 of the interlayer dielectric film 38-1 may be equal to or less than the width D1 of the mesa portion 60 in the array direction. Making the thickness H1 of the interlayer dielectric film 38-1 equal to or less than the width D1 of the mesa portion 60 in the array direction can reduce an aspect ratio of the contact hole 54-1, to improve alignment accuracy between the mesa portion 60 and the contact hole 54-1. It should be noted that a sum of the thickness H1 of the interlayer dielectric film 38-1 and a thickness of the gate dielectric film 42 is preferably equal to or less than the width D1 of the mesa portion 60 in the array direction.

A thickness H2 of the interlayer dielectric film 38-2 may be larger than the thickness H1 of the interlayer dielectric film 38-1. Making the thickness H2 of the interlayer dielectric film 38-2 larger than the thickness H1 of the interlayer dielectric film 38-1 allows increase in the thickness of the interlayer dielectric film 38-2, and can ensure insulation between the gate conductive portion 44 and the emitter electrode 52.

The thickness H1 of the interlayer dielectric film 38-1 may be 0.1 μm or more. The thickness H1 of the interlayer dielectric film 38-1 may be 0.2 μm or more. The thickness H1 of the interlayer dielectric film 38-1 may be 0.3 μm or more. The thickness H1 of the interlayer dielectric film 38-1 may be 0.8 μm or less. The thickness H1 of the interlayer dielectric film 38-1 may be 0.5 μm or less. The thickness H2 of the interlayer dielectric film 38-2 may be 0.5 μm or more. The thickness H2 of the interlayer dielectric film 38-2 may be 1.0 μm or more. The width D1 of the mesa portion 60 may be 0.5 μm or more and 1.5 μm or less. A sum of the thickness H1 of the interlayer dielectric film 38-1 and the thickness H2 of the interlayer dielectric film 38-2 may be 1.0 μm or more and 2.0 μm or less.

The interlayer dielectric film 38-1 preferably has higher processing accuracy than the interlayer dielectric film 38-2. The processing accuracy of the interlayer dielectric film 38-1 is higher than that of the interlayer dielectric film 38-2, so that the contact resistance between the emitter electrode 52 and the mesa portion 60 can be reduced. In addition, the interlayer dielectric film 38-2 preferably has a higher insulation property than the interlayer dielectric film 38-1. The insulation property of the interlayer dielectric film 38-2 is higher than that of the interlayer dielectric film 38-1, so that the insulation between the gate conductive portion 44 and the emitter electrode 52 can be ensured. As an example, the interlayer dielectric film 38-1 is a High Temperature Oxidation (HTO) film (high temperature oxidation film), and the interlayer dielectric film 38-2 is a Boro Phospho Silicate Glass (BPSG) film.

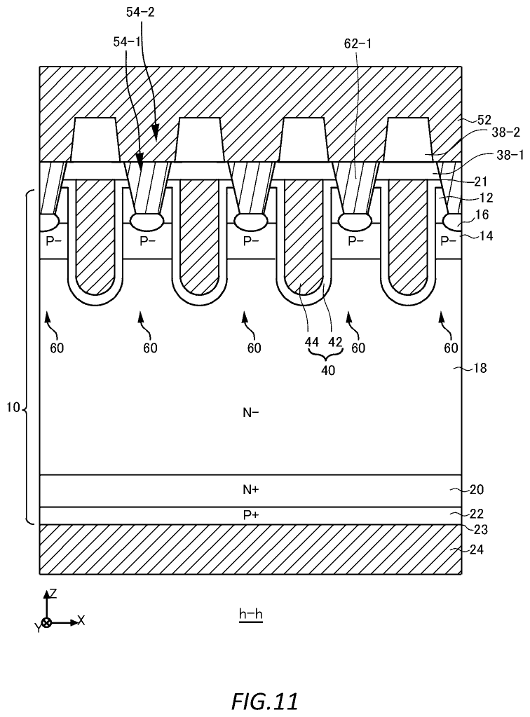

FIG. 11 shows another example of the cross section h-h in FIG. 9. FIG. 11 is different from FIG. 10 in that it has a configuration of the plug metal 62-1 and a diffusion region 16. Except for that, a configuration in FIG. 11 may be the same as that in FIG. 10.

In the present example, the plug metal 62-1 is provided in the semiconductor substrate 10. The plug metal 62-1 may be provided in a trench provided in the mesa portion 60 of the semiconductor substrate 10.

In the present example, the diffusion region 16 is provided below the plug metal 62-1. The diffusion region 16 may be provided between the base region 14 and the plug metal 62-1. The diffusion region 16 may be provided so as not to be in contact with the gate trench portion 40. The diffusion region 16 is of the P+ type, as an example. Electron holes directed from a lower surface 23 side to the emitter region 12 when the semiconductor apparatus 100 is turned off can flow into the plug metal 62-1 via the diffusion region 16. This can reduce a resistance of a path through which the electron holes pass, and can suppress latch-up.

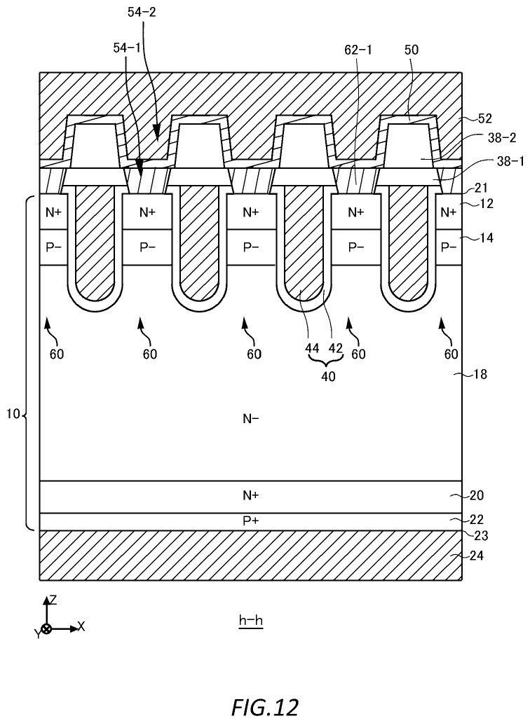

FIG. 12 shows another example of the cross section h-h in FIG. 9. FIG. 12 is different from FIG. 10 in that it has a barrier metal 50. Except for that, a configuration in FIG. 12 may be the same as that in FIG. 10.

The barrier metal 50 may be provided below the emitter electrode 52. In the present example, the barrier metal 50 is provided between the emitter electrode 52 and the plug metal 62-1. In addition, in the present example, the barrier metal 50 is provided between the emitter electrode 52 and the interlayer dielectric film 38-2. The barrier metal 50 may be provided between the emitter electrode 52 and the interlayer dielectric film 38-1. The barrier metal 50 may contain titanium. The barrier metal 50 may be formed of titanium, titanium compound, or the like. Providing the barrier metal 50 can prevent a metal element contained in the emitter electrode 52 from diffusing into the interlayer dielectric film 38 and the plug metal 62-1.

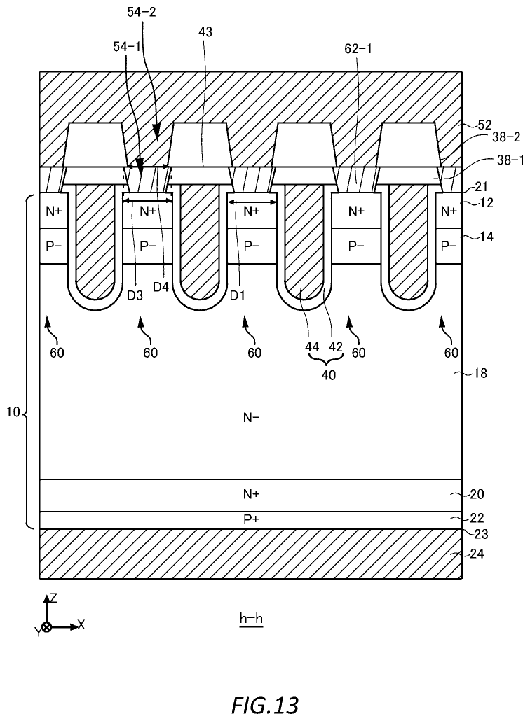

FIG. 13 shows another example of the cross section h-h in FIG. 9. FIG. 13 is different from FIG. 10 in the width D4 of the contact hole 54-2. Except for that, a configuration in FIG. 13 may be the same as that in FIG. 10.

In the present example, the width D4 of the contact hole 54-2 in the array direction is smaller than the width D3 of the contact hole 54-1 in the array direction at the boundary height. That is, in the present example, the entire upper surface 43 of the interlayer dielectric film 38-1 is covered with the interlayer dielectric film 38-2. The width D4 of the contact hole 54-2 may be 0.9 times or less the width D3 of the contact hole 54-1. The width D4 of the contact hole 54-2 may be 0.8 times or less the width D3 of the contact hole 54-1. The width D4 of the contact hole 54-2 may be 0.5 times or more the width D3 of the contact hole 54-1. If the width D1 of the mesa portion 60 is large, even making the width D4 of the contact hole 54-2 smaller than the width D3 of the contact hole 54-1 allows reliable contact between a contact portion (the plug metal 62-1) and the emitter electrode 52. Accordingly, a shape of the interlayer dielectric film 38 can be flexibly changed.

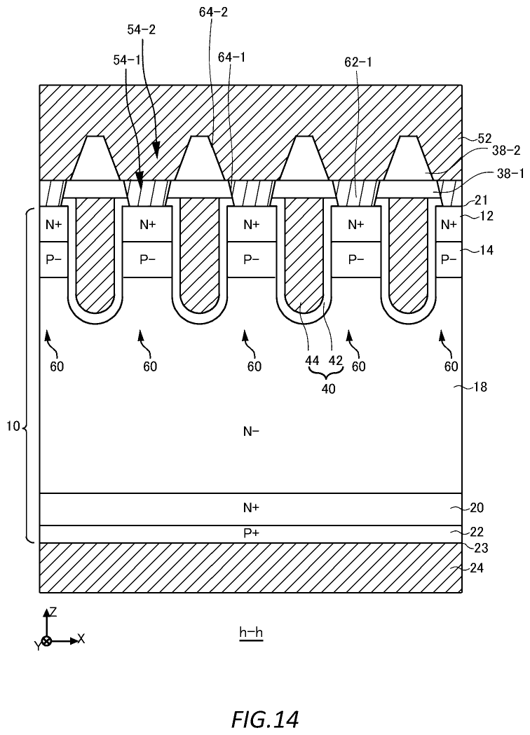

FIG. 14 shows another example of the cross section h-h in FIG. 9. FIG. 14 is different from FIG. 10 in a shape of the interlayer dielectric film 38-2. Except for that, a configuration in FIG. 14 may be the same as that in FIG. 10.

In the present example, a side wall 64-1 of the contact hole 54-1 is steeper than a side wall 64-2 of the contact hole 54-2. The fact that the side wall 64-1 of the contact hole 54-1 is steeper than the side wall 64-2 of the contact hole 54-2 may be that an angle formed by a slope of the side wall 64-1 of the contact hole 54-1 and the upper surface 21 of the semiconductor substrate 10 is greater than an angle formed by a slope of the side wall 64-2 of the contact hole 54-2 and the upper surface 21 of the semiconductor substrate 10. The side wall 64-1 of the contact hole 54-1 being steeper than the side wall 64-2 of the contact hole 54-2 makes it possible to provide reliable contact between a contact portion (the plug metal 62-1) and the emitter electrode 52 while ensuring insulation between the gate conductive portion 44 and the emitter electrode 52.

The slope of the side wall 64-1 of the contact hole 54-1 may be the slope of the side wall 64-1 of the contact hole 54-1 at a boundary height. That is, the slope of the side wall 64-1 of the contact hole 54-1 may be the slope of the side wall 64-1 of the contact hole 54-1 at an upper end of the contact hole 54-1. The slope of the side wall 64-1 of the contact hole 54-1 may be an average slope of the side wall 64-1 of the contact hole 54-1 from a lower end to an upper end of the side wall 64-1 of the contact hole 54-1. In addition, the slope of the side wall 64-1 of the contact hole 54-1 may be the slope of the side wall 64-1 at a center in the height direction. The slope of the side wall 64-2 of the contact hole 54-2 may be the slope of the side wall 64-2 of the contact hole 54-2 at the boundary height. That is, the slope of the side wall 64-2 of the contact hole 54-2 may be the slope of the side wall 64-2 of the contact hole 54-2 at a lower end of the contact hole 54-2. The slope of the side wall 64-2 of the contact hole 54-2 may be an average slope of the side wall 64-2 of the contact hole 54-2 from a lower end to an upper end of the side wall 64-2 of the contact hole 54-2. In addition, the slope of the side wall 64-2 of the contact hole 54-2 may be the slope of the side wall 64-2 at a center in the height direction.

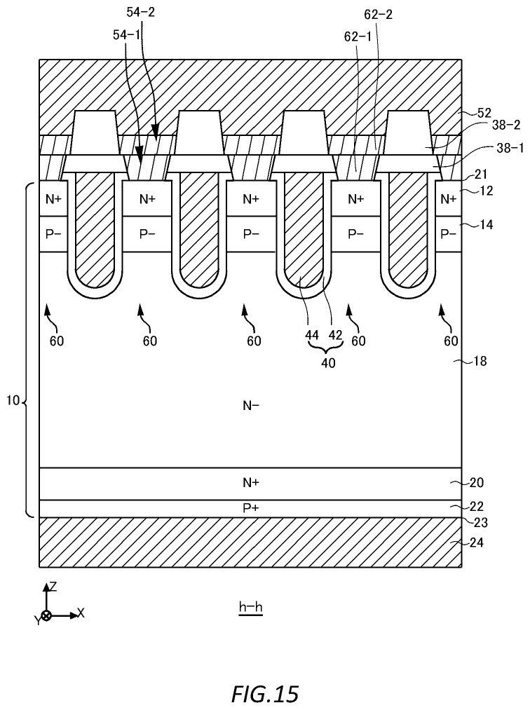

FIG. 15 shows another example of the cross section h-h in FIG. 9. FIG. 15 is different from FIG. 10 in that it has a plug metal 62-2. Except for that, a configuration in FIG. 15 may be the same as that in FIG. 10.

At least part of the plug metal 62-2 is provided in the contact hole 54-2. In the present example, the entire plug metal 62-2 is provided in the contact hole 54-2. In the present example, the emitter electrode 52 is provided in the contact hole 54-2 above the plug metal 62-2. The plug metal 62-2 may be provided above the plug metal 62-1. In the present example, the plug metal 62-2 is provided on an upper surface of the plug metal 62-1. The plug metal 62-2 may be formed of a high-melting point material such as Ta, W, or Mo, like the plug metal 62-1. The plug metal 62-2 is an example of a contact portion. Providing the plug metal 62-2 can reduce a contact resistance between the emitter electrode 52 and the mesa portion 60.

It should be noted that polysilicon instead of the plug metal 62-1 may be provided in the contact hole 54-1. The polysilicon may be provided during formation of the gate conductive portion 44 and the gate runner 46.

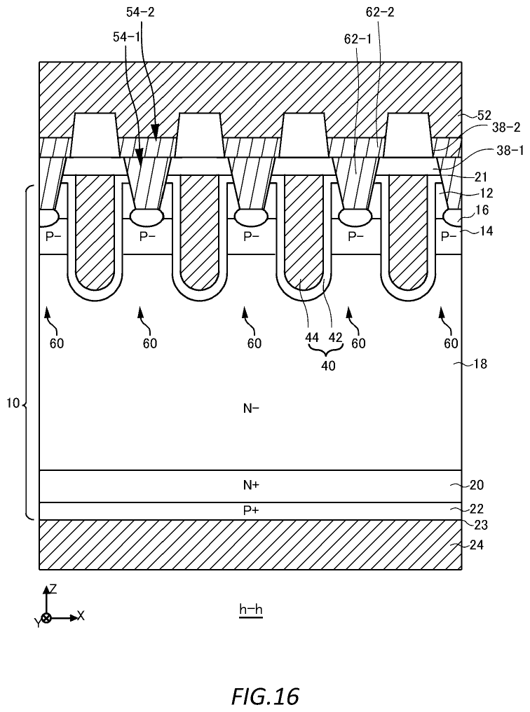

FIG. 16 shows another example of the cross section h-h in FIG. 9. FIG. 16 is different from FIG. 15 in that it has a configuration of the plug metal 62-1 and a diffusion region 16. Specifically, the diffusion region 16 is provided at a bottom portion of a trench provided in the mesa portion 60 of the semiconductor substrate 10, and the plug metal 62-1 is provided in the trench. Except for that, a configuration in FIG. 16 may be the same as that in FIG. 15. Description of the same reference numeral will be omitted.

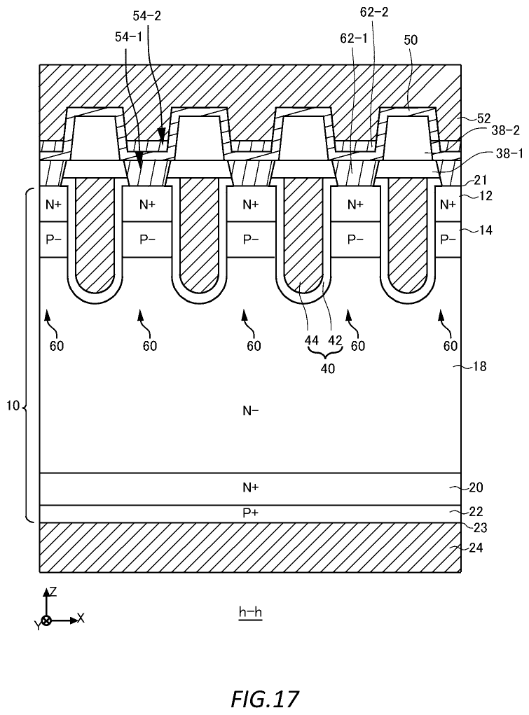

FIG. 17 shows another example of the cross section h-h in FIG. 9. FIG. 17 is different from FIG. 15 in that it has the barrier metal 50. Except for that, a configuration in FIG. 17 may be the same as that in FIG. 15. Description of the same reference numeral will be omitted.

The barrier metal 50 may be provided below the emitter electrode 52. In the present example, the barrier metal 50 is provided between the plug metal 62-1 and the plug metal 62-2. In addition, in the present example, the barrier metal 50 is provided between the emitter electrode 52 and the interlayer dielectric film 38-2. The barrier metal 50 may be provided between the emitter electrode 52 and the interlayer dielectric film 38-1.

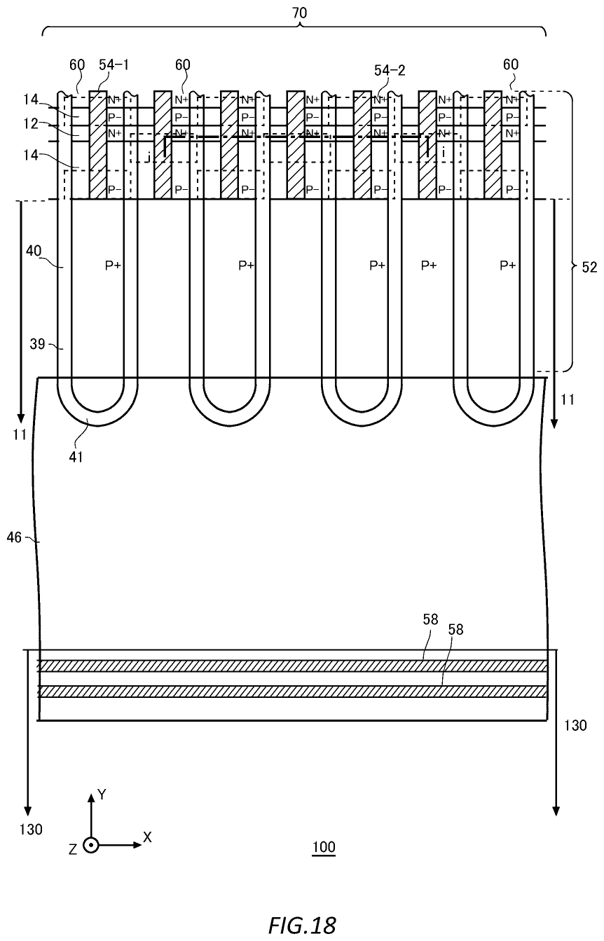

FIG. 18 shows another exemplary embodiment of the region D in FIG. 1. The semiconductor apparatus 100 in FIG. 18 is different from the semiconductor apparatus 100 in FIG. 9 in a configuration of the contact hole 54. Except for that, a configuration of the semiconductor apparatus 100 in FIG. 18 may be the same as that of the semiconductor apparatus 100 in FIG. 9. FIG. 18 shows a shape of the contact hole 54-1 at the upper surface 21 of the semiconductor substrate 10, and a shape of the contact hole 54-2 at a boundary height between the interlayer dielectric film 38-1 and the interlayer dielectric film 38-2.

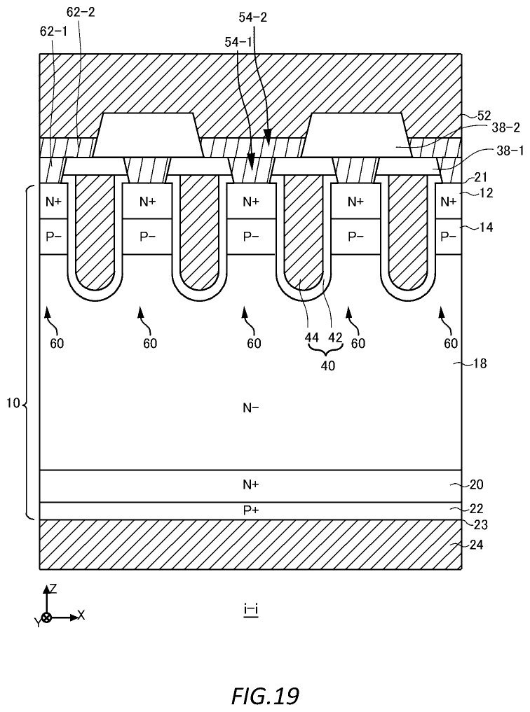

FIG. 19 shows an example of a cross section i-i in FIG. 18. The cross section i-i is an XZ plane passing through the emitter region 12. It should be noted that the dimensions in FIG. 19 do not necessarily match the dimensions in FIG. 18. The semiconductor apparatus 100 in the present example includes the semiconductor substrate 10, the interlayer dielectric film 38, the emitter electrode 52, and the collector electrode 24 in the cross section. The semiconductor apparatus 100 in FIG. 19 is different from the semiconductor apparatus 100 in FIG. 15 in configurations of the contact hole 54-2, the interlayer dielectric film 38-2, and the plug metal 62-2. Except for that, a configuration of the semiconductor apparatus 100 in FIG. 19 may be the same as that of the semiconductor apparatus 100 in FIG. 15.

In the present example, an interval at which contact holes 54-1 are arranged in the array direction is different from an interval at which contact holes 54-2 are arranged in the array direction. The interval at which the contact holes 54-1 are arranged is a width for one mesa portion 60. That is, the contact hole 54-1 and the plug metal 62-1 are provided in each mesa portion 60. The interval at which the contact holes 54-2 are arranged is a width for two mesa portions 60. That is, mesa portions 60 above which the contact holes 54-2 and plug metals 62-2 are provided and mesa portions 60 above which the contact holes 54-2 and the plug metals 62-2 are not provided are alternately arranged. Mesa portions 60 above which interlayer dielectric films 38-2 are provided and mesa portions 60 above which the interlayer dielectric films 38-2 are not provided may be alternately provided. At least one contact hole 54-1 may be covered with the interlayer dielectric film 38-2. Such a configuration can increase a width of the plug metal 62-2 in the array direction, and allows reliable contact between a contact portion (the plug metal 62-1) and the emitter electrode 52.

In addition, in FIG. 18, the contact holes 54-2 are discretely provided in a top view. The contact holes 54-2 may be discretely provided in the array direction. The contact holes 54-2 may be discretely provided in the extending direction. Discretely arranging the contact holes 54-2 can connect each mesa portion 60 to the emitter electrode 52 even when a width of the plug metal 62-2 is increased.

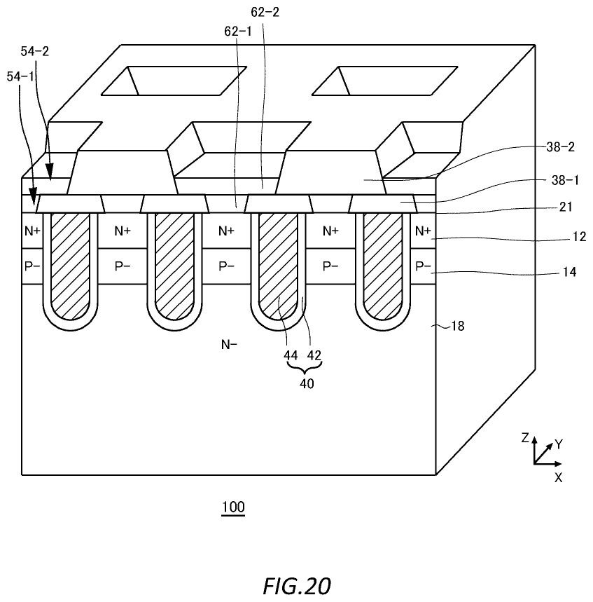

FIG. 20 shows a perspective view of the semiconductor apparatus 100 in FIG. 18. FIG. 20 shows arrangement of the interlayer dielectric film 38-1 and the interlayer dielectric film 38-2 in the semiconductor substrate 10. It should be noted that, in FIG. 20, illustration of the vicinity of the lower surface 23 of the semiconductor substrate 10 is omitted. As shown in FIG. 20 as well, the contact holes 54-2 are discretely provided in a top view. The contact holes 54-2 and the plug metals 62-2 in the present example are discretely provided in both the X axis direction and the Y axis direction. In a certain XY cross section, a plurality of plug metals 62-1 are provided side by side in the X axis direction. The plug metals 62-2 are arranged above some of the plurality of plug metals 62-1. Above some others of the plurality of plug metals 62-1, the plug metals 62-2 are not arranged, but the interlayer dielectric films 38-2 are provided. More specifically, plug metals 62-1 above which the plug metals 62-2 are arranged and plug metals 62-1 above which the plug metals 62-2 are not arranged are alternately arranged in the X axis direction. In the Y axis direction, the plug metals 62-1 are continuously arranged, and the plug metals 62-2 are discretely arranged above the plug metals 62-1.

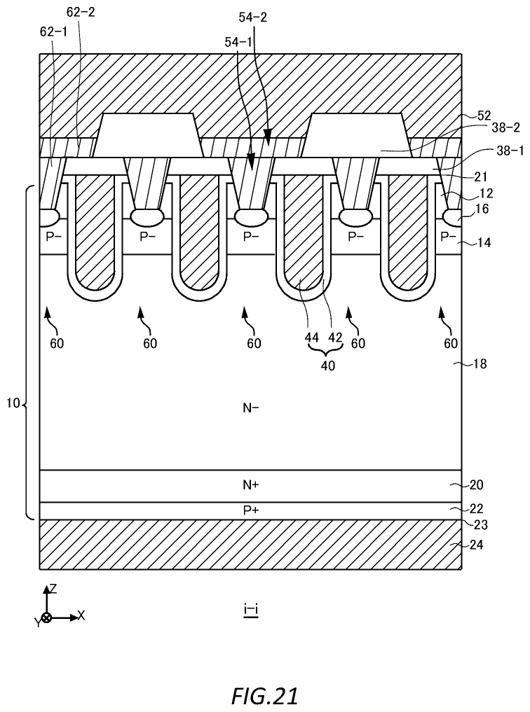

FIG. 21 shows another example of the cross section i-i in FIG. 18. FIG. 21 is different from FIG. 19 in that it has a configuration of the plug metal 62-1 and a diffusion region 16. Except for that, a configuration in FIG. 21 may be the same as that in FIG. 19. Description of the same reference numeral will be omitted.

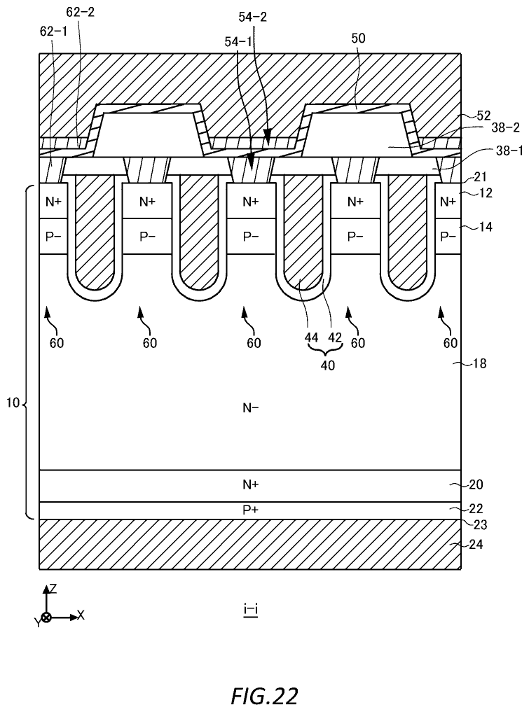

FIG. 22 shows another example of the cross section i-i in FIG. 18. FIG. 22 is different from FIG. 19 in that it has the barrier metal 50. Except for that, a configuration in FIG. 22 may be the same as that in FIG. 19. Description of the same reference numeral will be omitted.

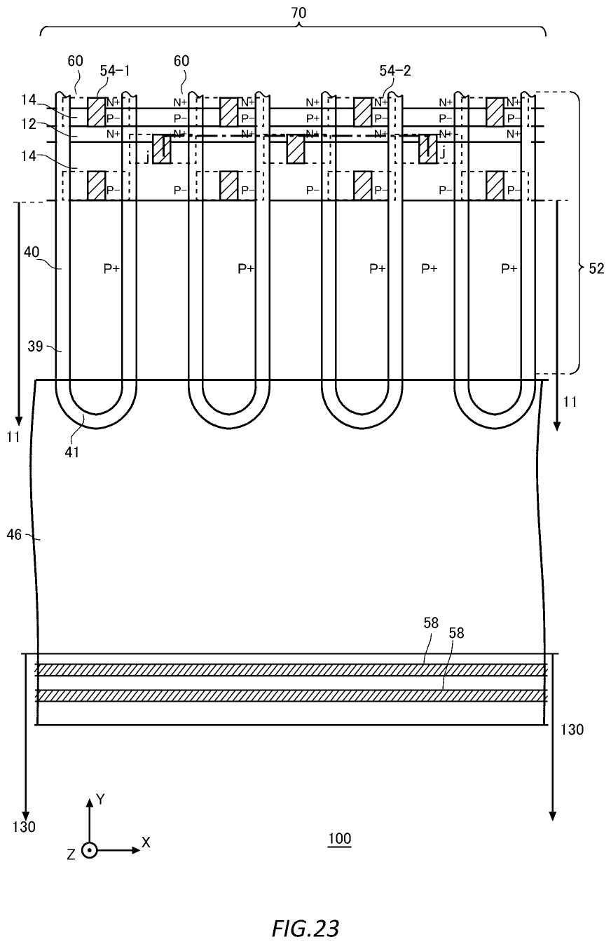

FIG. 23 shows another exemplary embodiment of the region D in FIG. 1. The semiconductor apparatus 100 in FIG. 23 is different from the semiconductor apparatus 100 in FIG. 18 in a configuration of the contact hole 54-1. Except for that, a configuration of the semiconductor apparatus 100 in FIG. 23 may be the same as that of the semiconductor apparatus 100 in FIG. 18. FIG. 23 shows a shape of the contact hole 54-1 at the upper surface 21 of the semiconductor substrate 10, and a shape of the contact hole 54-2 at a boundary height between the interlayer dielectric film 38-1 and the interlayer dielectric film 38-2.

In FIG. 23, the contact holes 54-1 are discretely provided in a top view. The contact holes 54-1 may be discretely provided in the array direction. The contact holes 54-1 may be discretely provided in the extending direction. The contact hole 54-1 may be provided only in a region overlapping the contact hole 54-2 in a top view. Discretely arranging the contact holes 54-1 provides many side walls of the contact holes 54-1 in the extending direction, and can increase contact area.

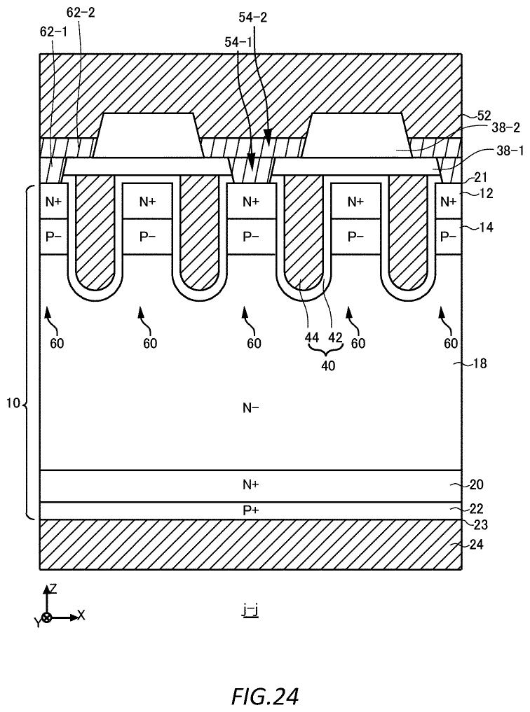

FIG. 24 shows an example of a cross section j-j in FIG. 23. The cross section j-j is an XZ plane passing through the emitter region 12. It should be noted that the dimensions in FIG. 24 do not necessarily match the dimensions in FIG. 23. The semiconductor apparatus 100 in the present example includes the semiconductor substrate 10, the interlayer dielectric film 38, the emitter electrode 52, and the collector electrode 24 in the cross section. The semiconductor apparatus 100 in FIG. 24 is different from the semiconductor apparatus 100 in FIG. 19 in configurations of the contact hole 54-1, the interlayer dielectric film 38-1, the plug metal 62-1, and the gate dielectric film 42. Except for that, a configuration of the semiconductor apparatus 100 in FIG. 24 may be the same as that of the semiconductor apparatus 100 in FIG. 19.

An interval at which the contact holes 54-1 are arranged is a width for two mesa portions 60. That is, mesa portions 60 above which the contact holes 54-1 and the plug metals 62-1 are provided and mesa portions 60 above which the contact holes 54-1 and the plug metals 62-1 are not provided are alternately arranged. The contact holes 54-1 and the plug metals 62-1 may be provided above mesa portions 60 above which the interlayer dielectric films 38-2 are not provided.

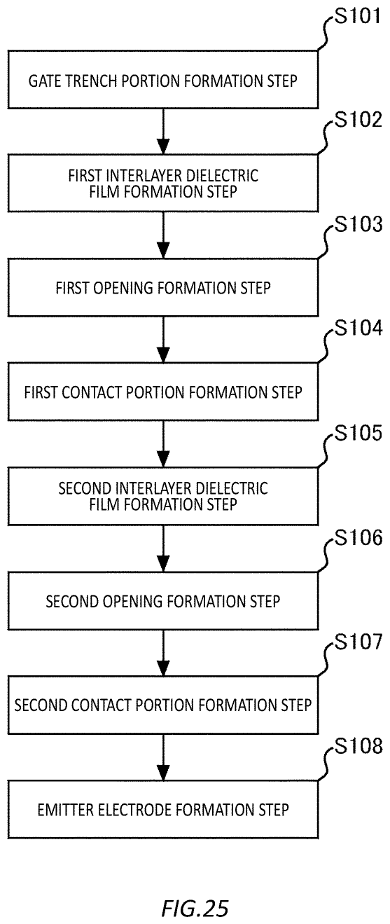

FIG. 25 illustrates an example of a flowchart of a method for manufacturing the semiconductor apparatus 100 shown in FIG. 15. The method for manufacturing the semiconductor apparatus 100 includes a gate trench portion formation step S101, a first interlayer dielectric film formation step S102, a first opening formation step S103, a first contact portion formation step S104, a second interlayer dielectric film formation step S105, a second opening formation step S106, a second contact portion formation step S107, and an emitter electrode formation step S108.

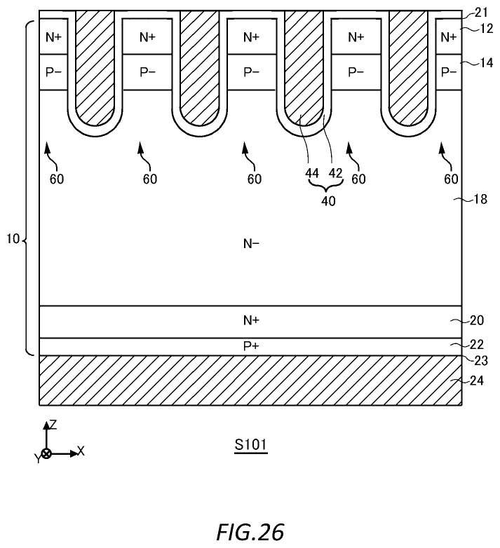

FIG. 26 shows an example of the gate trench portion formation step S101. In the gate trench portion formation step S101, the gate trench portion 40 is formed at the upper surface 21 of the semiconductor substrate 10. In the gate trench portion formation step S101, a gate trench is first provided which is provided at the upper surface 21 of the semiconductor substrate 10. The gate trench may be formed by a well known method such as etching. Subsequently, the gate dielectric film 42 and the gate conductive portion 44 are formed in the gate trench. The gate dielectric film 42 may be formed by oxidizing the semiconductor substrate 10 by a well known method. The gate dielectric film 42 may be provided above the mesa portion 60. The gate conductive portion 44 may be formed by depositing polysilicon or the like by a well known method such as a CVD method.

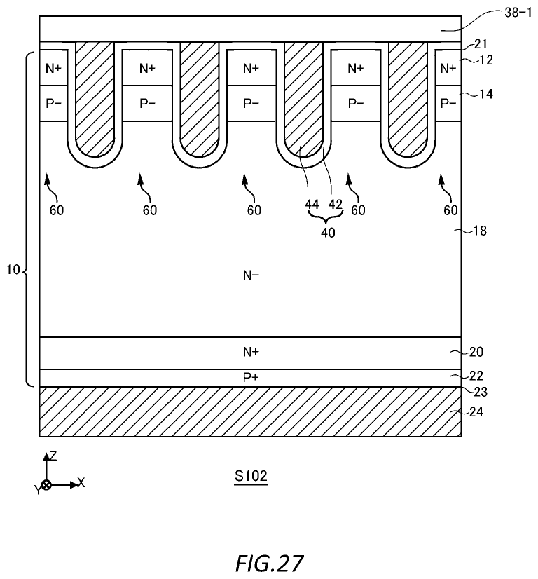

FIG. 27 shows an example of the first interlayer dielectric film formation step S102. In the first interlayer dielectric film formation step S102, the interlayer dielectric film 38-1 is formed above the semiconductor substrate 10. The interlayer dielectric film 38-1 is an HTO film, as an example. The interlayer dielectric film 38-1 may be a BPSG film. The interlayer dielectric film 38-1 may be formed by a well known method.

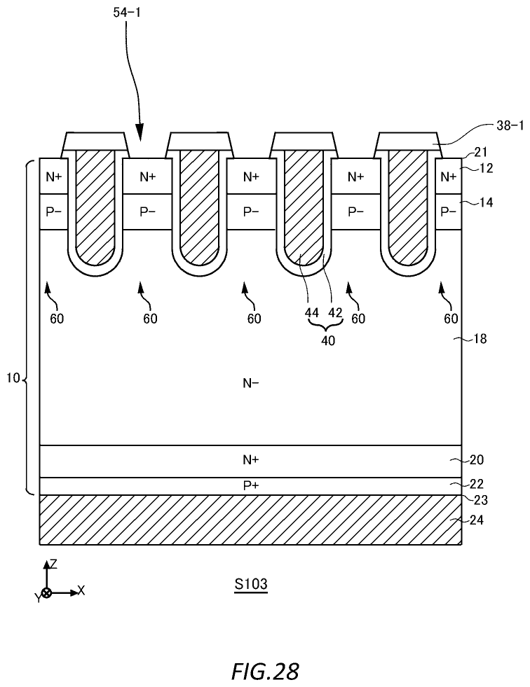

FIG. 28 shows an example of the first opening formation step S103. In the first opening formation step S103, the contact hole 54-1 is formed in the interlayer dielectric film 38-1. In the first opening formation step S103, the contact hole 54-1 may be formed by etching the interlayer dielectric film 38-1 and the gate dielectric film 42 by a well known method.

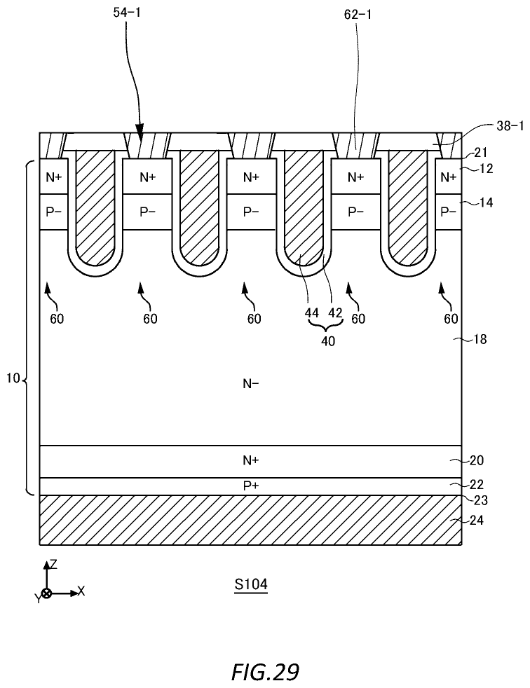

FIG. 29 shows an example of the first contact portion formation step S104. In the first contact portion formation step S104, the plug metal 62-1 is formed in the contact hole 54-1. In the first contact portion formation step S104, the plug metal 62-1 is formed in at least part of the contact hole 54-1. In the present example, the plug metal 62-1 is formed in the entire contact hole 54-1. The plug metal 62-1 may be formed by depositing a high-melting point metal material such as Ta, W, or Mo by a well known method such as sputtering.

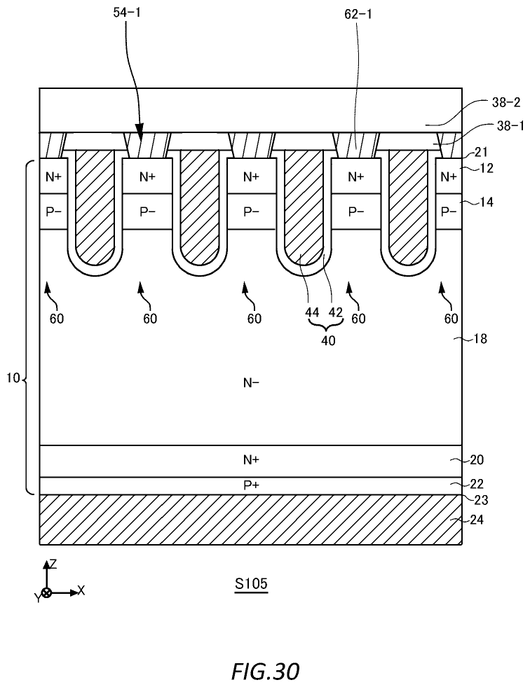

FIG. 30 shows an example of the second interlayer dielectric film formation step S105. In the second interlayer dielectric film formation step S105, the interlayer dielectric film 38-2 is formed above the semiconductor substrate 10. In the present example, the interlayer dielectric film 38-2 is formed which is to be stacked on the interlayer dielectric film 38-1 and the plug metal 62-1. The interlayer dielectric film 38-2 is a BPSG film, as an example. The interlayer dielectric film 38-2 may be an HTO film. The interlayer dielectric film 38-2 may be formed by a well known method. Heat resisting temperature of the interlayer dielectric film 38-2 may be lower than that of the interlayer dielectric film 38-1.

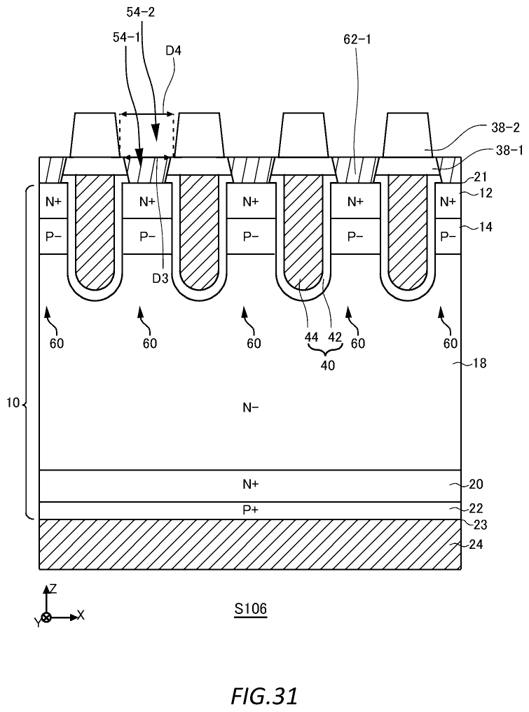

FIG. 31 shows an example of the second opening formation step S106. In the second opening formation step S106, the contact hole 54-2 is formed in the interlayer dielectric film 38-2. In the first opening formation step S106, the contact hole 54-1 may be formed by etching the interlayer dielectric film 38-2 by a well known method. The contact hole 54-2 is formed in the interlayer dielectric film 38-2 such that the width D3 of the contact hole 54-1 and the width D4 of the contact hole 54-2 in the array direction are different, at a boundary height between the interlayer dielectric film 38-1 and the interlayer dielectric film 38-2.

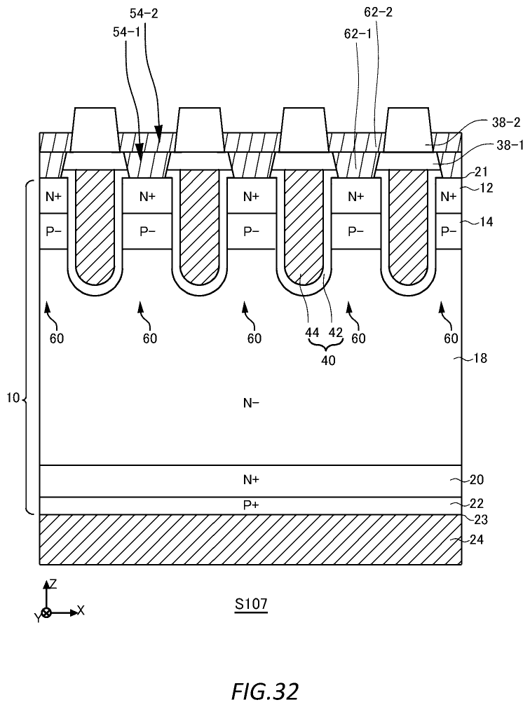

FIG. 32 shows an example of the second contact portion formation step S107. In the second contact portion formation step S107, the plug metal 62-2 is formed in at least part of the contact hole 54-2. The plug metal 62-2 may be formed by depositing a metal material such as Ta, W, or Mo by a well known method such as sputtering, like the plug metal 62-1. The barrier metal 50 may be provided between the plug metal 62-1 and the plug metal 62-2.

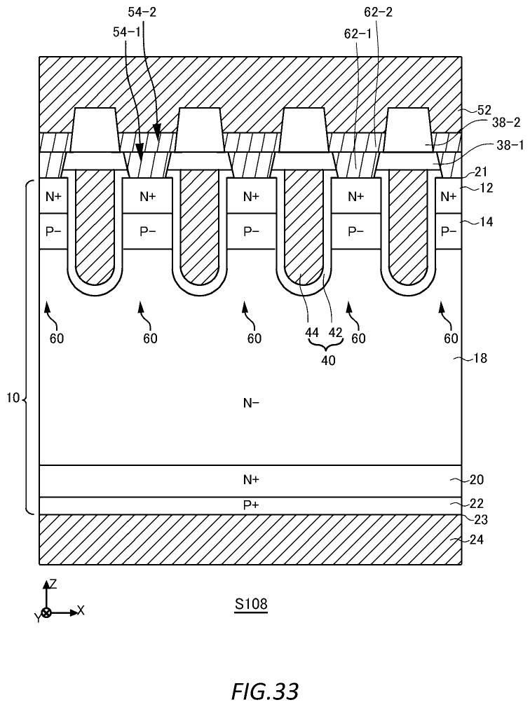

FIG. 33 shows an example of the emitter electrode formation step S108. In the emitter electrode formation step S108, the emitter electrode 52 is formed above the semiconductor substrate 10. In the present example, the emitter electrode 52 is formed above the interlayer dielectric film 38-2 and the plug metal 62-2. In addition, the emitter electrode 52 may be provided in the contact hole 54-2.

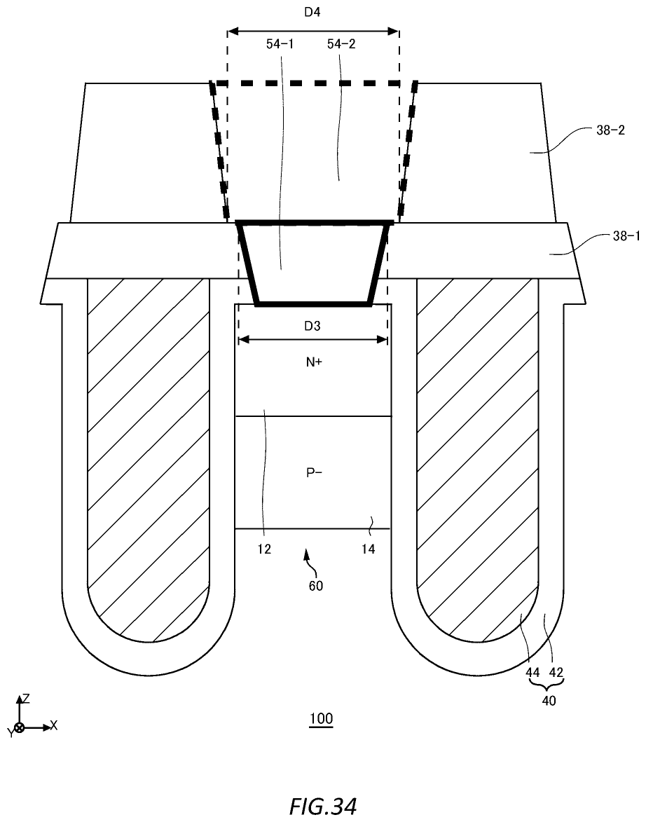

FIG. 34 shows details of the semiconductor apparatus 100 shown in FIG. 10. FIG. 34 shows one mesa portion 60 and two gate trench portions 40. It should be noted that, in FIG. 34, the plug metal 62-1 and the emitter electrode 52 are omitted.

In FIG. 34, the contact hole 54-1 is a region enclosed by a thick line. The contact hole 54-1 is sandwiched between interlayer dielectric films 38-1 in the array direction. In the present example, at least part of the contact hole 54-1 is sandwiched between the interlayer dielectric films 38-1 in the array direction. In addition, the contact hole 54-1 is sandwiched between gate dielectric films 42 in the array direction. In the present example, at least part of the contact hole 54-1 is sandwiched between the gate dielectric films 42 in the array direction. In FIG. 34, the contact hole 54-2 is a region enclosed by a thick dotted line. The contact hole 54-2 is sandwiched between the interlayer dielectric films 38-2 in the array direction. In the present example, the entire contact hole 54-2 is sandwiched between the interlayer dielectric films 38-2 in the array direction.

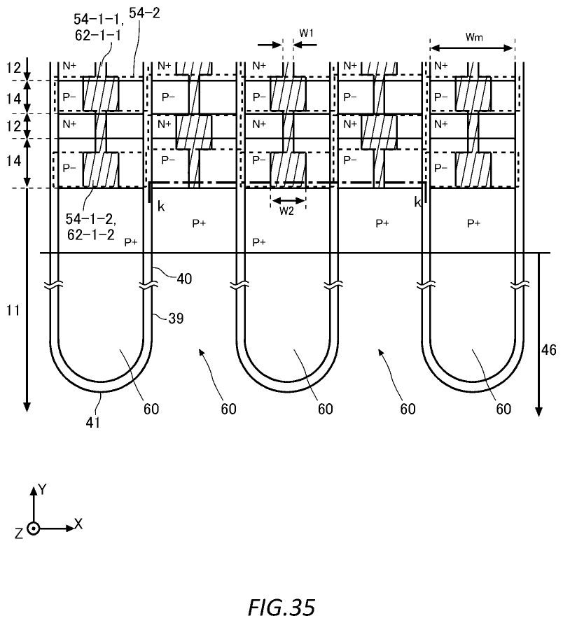

FIG. 35 shows another exemplary embodiment of the region D in FIG. 1. The semiconductor apparatus 100 in FIG. 35 is different from those in the examples described in FIG. 1 to FIG. 34 in structures of the contact hole 54-1 and the plug metal 62-1. Except for the contact hole 54-1 and the plug metal 62-1, a configuration of the semiconductor apparatus 100 in FIG. 35 may be similar to that of the semiconductor apparatus 100 according to any of the aspects described in FIG. 1 to FIG. 34. FIG. 35 shows a shape of the contact hole 54-1 and a shape of the plug metal 62-1 at the upper surface 21 of the semiconductor substrate 10 as well as a shape of the contact hole 54-2 at a boundary height between the interlayer dielectric film 38-1 and the interlayer dielectric film 38-2. As shown in FIG. 21 or the like, the plug metal 62-1 is provided in the contact hole 54-1 and in the semiconductor substrate 10 below the contact hole 54-1. The shape of the contact hole 54-1 and the shape of the plug metal 62-1 at the upper surface 21 may be the same.

As described in FIG. 2 or the like, the semiconductor apparatus 100 has a plurality of mesa portions 60. Each mesa portion 60 in the present example is provided between two gate trench portions 40. The mesa portion 60 extends in the extending direction (the Y axis direction in FIG. 35) at the upper surface 21 of the semiconductor substrate 10. That is, the Y axis direction is a longitudinal direction of the mesa portion 60.

The contact hole 54-1 has a first segment 54-1-1 and a second segment 54-1-2. The first segment 54-1-1 and the second segment 54-1-2 are provided side by side in the Y axis direction. In the example shown in FIG. 35, first segments 54-1-1 and second segments 54-1-2 are alternately arranged along the Y axis direction.

The plug metal 62-1 has a first segment 62-1-1 and a second segment 62-1-2. The first segment 62-1-1 and the second segment 62-1-2 are provided side by side in the Y axis direction. In the example shown in FIG. 35, first segments 62-1-1 and second segments 62-1-2 are alternately arranged along the Y axis direction.

A width of the first segment 54-1-1 of the contact hole 54-1 in the X axis direction and a width of the first segment 62-1-1 of the plug metal 62-1 are referred to as W1. A width of the second segment 54-1-2 of the contact hole 54-1 in the X axis direction and a width of the second segment 62-1-2 of the plug metal 62-1 are referred to as W2. A width W2 is larger than a width W1. The width W2 may be 30% or more and 60% or less of a width Wm of the mesa portion 60 in the X axis direction. The width W1 may be 10% or more and 40% or less of the width Wm of the mesa portion 60 in the X axis direction. The width W1, the width W2, and the width Wm may be widths at the upper surface 21 of the semiconductor substrate 10.

At least part of the first segment 62-1-1 of the plug metal 62-1 may be arranged at a position which does not overlap the contact hole 54-2. The entire first segment 62-1-1 may be arranged so as not to overlap the contact hole 54-2. The second segment 62-1-2 of the plug metal is provided in a range overlapping the contact hole 54-2 in the present example. In the present example, a range where the second segment 62-1-2 of the plug metal is provided in the Y axis direction matches a range where the second segment 54-1-2 of the contact hole 54-1 is provided. Providing the second segment 62-1-2 with a large width can easily extract holes.

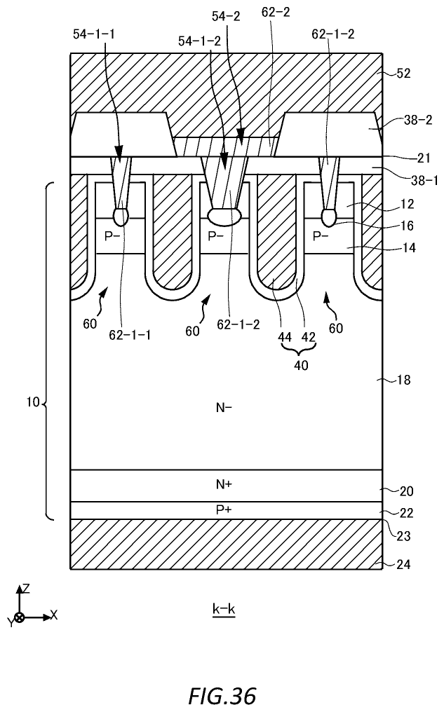

FIG. 36 shows an example of a cross section k-k in FIG. 35. The cross section k-k is an XZ plane passing through the emitter region 12. It should be noted that the dimensions in FIG. 36 do not necessarily match the dimensions in FIG. 35. As described in FIG. 35, a width of the second segment 62-1-2 of the plug metal 62-1 in the X axis direction is larger than a width of the first segment 62-1-1 in the X axis direction. This can reduce a resistance between the plug metal 62-1 and the plug metal 62-2, and can efficiently extract holes. In addition, reducing a width of the first segment 62-1-1 which is not connected to the plug metal 62-2 can maintain a distance between the first segment 62-1-1 and the gate trench portion 40, and can reduce an impact of the plug metal 62-1 on a channel.

The first segment 54-1-1 and the second segment 54-1-2 of the contact hole 54-1 may be formed in a common process by patterning a photomask. The first segment 62-1-1 and the second segment 62-1-2 of the plug metal 62-1 may be formed in a common process. The contact hole 54-1 and the plug metal 62-1 may have the same shape. The first segment 54-1-1 and the first segment 62-1-1 may have the same shape. The second segment 54-1-2 and the second segment 62-1-2 may have the same shape.

Lengths of the first segment 62-1-1 and the second segment 62-1-2 of the plug metal 62-1 in the Z axis direction may be the same or different. As an example, the second segment 62-1-2 of the plug metal 62-1 may be longer than the first segment 62-1-1. Similarly, depths of the first segment 54-1-1 and the second segment 54-1-2 of the contact hole 54-1 in the Z axis direction may be the same or different. As an example, the second segment 54-1-2 of the contact hole 54-2 may be formed up to a position deeper than the first segment 54-1-1. Lengthening the second segment 62-1-2 of the plug metal 62-1 can increase contact area between the second segment 62-1-2 and the semiconductor substrate 10, and can reduce a contact resistance between the second segment 62-1-2 and the semiconductor substrate 10. This further improves hole extraction efficiency.

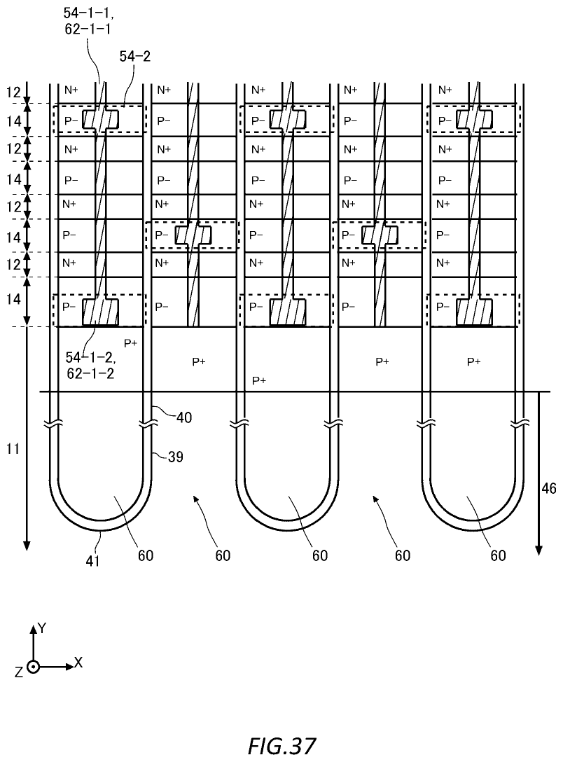

FIG. 37 shows another exemplary embodiment of the region D in FIG. 1. The semiconductor apparatus 100 in FIG. 37 is different from those in the examples described in FIG. 1 to FIG. 36 in structures of the contact hole 54-1 and the plug metal 62-1. Configurations of components other than the contact hole 54-1 and the plug metal 62-1 may be similar to those of the semiconductor apparatus 100 according to any of the aspects described in FIG. 1 to FIG. 36. FIG. 37 shows a shape of the contact hole 54-1 and a shape of the plug metal 62-1 at the upper surface 21 of the semiconductor substrate 10 as well as a shape of the contact hole 54-2 at a boundary height between the interlayer dielectric film 38-1 and the interlayer dielectric film 38-2.

The contact hole 54-1 in the present example has the first segment 54-1-1 and the second segment 54-1-2, like the example shown in FIG. 35. The plug metal 62-1 in the present example has the first segment 62-1-1 and the second segment 62-1-2, like the example shown in FIG. 35. Note that arrangement of each segment in the Y axis direction is different from that in the example shown in FIG. 35. Other structures may be similar to those in the example described in FIG. 35.

Each mesa portion 60 has a region of the P type and the emitter region 12 exposed on the upper surface 21 of the semiconductor substrate 10. The emitter regions 12 and regions of the P type are alternately arranged in the Y axis direction. In the example shown in FIG. 37, the base region 14 corresponds to the region of the P type.

At least part of the second segment 54-1-2 of the contact hole 54-1 is arranged so as to overlap the base region 14. In the example shown in FIG. 37, the entire second segment 54-1-2 is arranged so as to overlap the base region 14. At least part of the first segment 54-1-1 of the contact hole 54-1 is arranged so as to overlap the emitter region 12. In the example shown in FIG. 37, the first segment 54-1-1 is provided throughout the Y axis direction of the emitter region 12. The first segment 54-1-1 may be provided in part of the base region 14 as well.

Arrangement of the first segment 62-1-1 of the plug metal 62-1 is similar to the arrangement of the first segment 54-1-1 of the contact hole 54-1, and arrangement of the second segment 62-1-2 is similar to arrangement of the second segment 54-1-2. According to the present example, the second segment 54-1-2 and the second segment 62-1-2 with a large width are arranged so as not to overlap the emitter region 12. This can keep a distance between the second segment 54-1-2 and the second segment 62-1-2, and a channel formed below the emitter region 12, and can reduce an impact of the second segment 54-1-2 and the second segment 62-1-2 on the channel. The second segment 54-1-2 and the second segment 62-1-2 may be provided apart from the emitter region 12 in the Y axis direction.

The second segment 54-1-2 and the second segment 62-1-2 may be provided in all the base regions 14 at the upper surface of the mesa portion 60, or may be provided in some of the base regions 14. In the example shown in FIG. 37, the second segment 54-1-2 and the second segment 62-1-2 are provided only in some of the base regions 14 among a plurality of base regions 14 arranged along the Y axis direction. The second segments 54-1-2 and the second segments 62-1-2 may be arranged at regular intervals or irregular intervals in the Y axis direction. Such arrangement can reduce the second segment 54-1-2 and the second segment 62-1-2, to reduce the impact of the second segment 54-1-2 and the second segment 62-1-2 on the channel. In two mesa portions 60 which are adjacent to each other in the X axis direction, positions in the Y axis direction where the second segment 54-1-2 and the second segment 62-1-2 are provided may be different. This can arrange the second segment 54-1-2 and the second segment 62-1-2 in an XY plane more equally, and can equalize hole extraction efficiency in the XY plane.

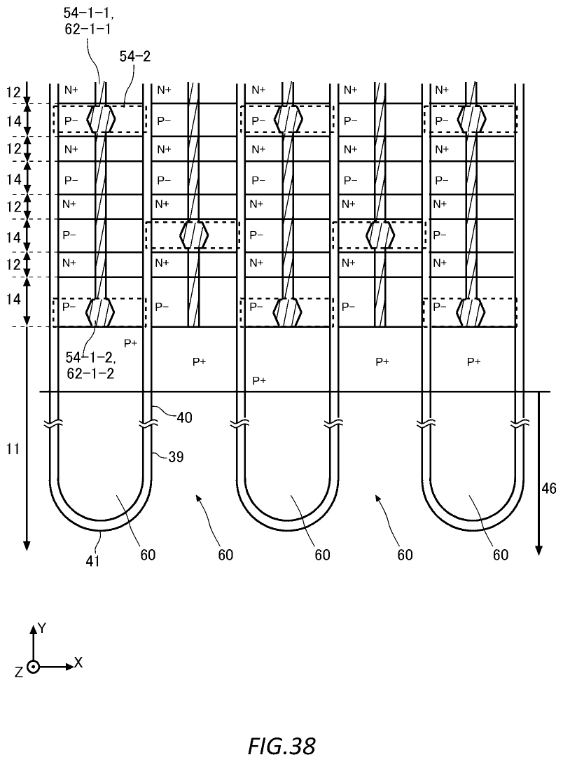

FIG. 38 shows another exemplary embodiment of the region D in FIG. 1. The semiconductor apparatus 100 in FIG. 38 is different from those in the examples described in FIG. 1 to FIG. 37 in structures of the contact hole 54-1 and the plug metal 62-1. In the example shown in FIG. 38, shapes of the contact hole 54-1 and the plug metal 62-1 in the example shown in FIG. 37 are changed.

The second segment 54-1-2 of the contact hole 54-1 and the second segment 62-1-2 of the plug metal 62-1 in the present example have an N-gonal shape at the upper surface 21 of the semiconductor substrate 10. Note that N is an integer of 5 or more. The second segment 54-1-2 and the second segment 62-1-2 shown in FIG. 37 or the like have a rectangular shape. Meanwhile, the second segment 54-1-2 and the second segment 62-1-2 in the present example have a rectangular shape with chamfered corners. Having such a shape makes it easy to keep a distance between the second segment 54-1-2 and the second segment 62-1-2, and a channel. As described above, the channel is formed in a surface layer of the base region 14 in contact with the gate trench portion 40, below the emitter region 12.

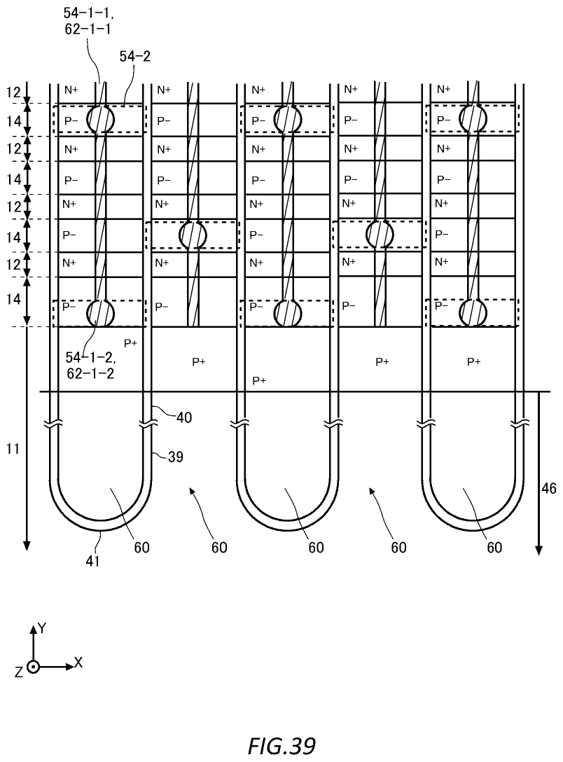

FIG. 39 shows another exemplary embodiment of the region D in FIG. 1. The semiconductor apparatus 100 in FIG. 39 is different from those in the examples described in FIG. 1 to FIG. 38 in structures of the contact hole 54-1 and the plug metal 62-1. In the example shown in FIG. 39, shapes of the contact hole 54-1 and the plug metal 62-1 in the example shown in FIG. 37 are changed.

The second segment 54-1-2 of the contact hole 54-1 and the second segment 62-1-2 of the plug metal 62-1 in the present example have an outer shape partially curved, at the upper surface 21 of the semiconductor substrate 10. The second segment 54-1-2 and the second segment 62-1-2 shown in FIG. 37 or the like have a rectangular shape. Meanwhile, the second segment 54-1-2 and the second segment 62-1-2 in the present example may have a rectangular shape with rounded corners. The second segment 54-1-2 and the second segment 62-1-2 may have a shape including part of a circle, may have a shape including part of an oval, may have a shape including part of an ellipse, or may have a shape with another curve. Having such a shape makes it easy to keep a distance between the second segment 54-1-2 and the second segment 62-1-2, and a channel.

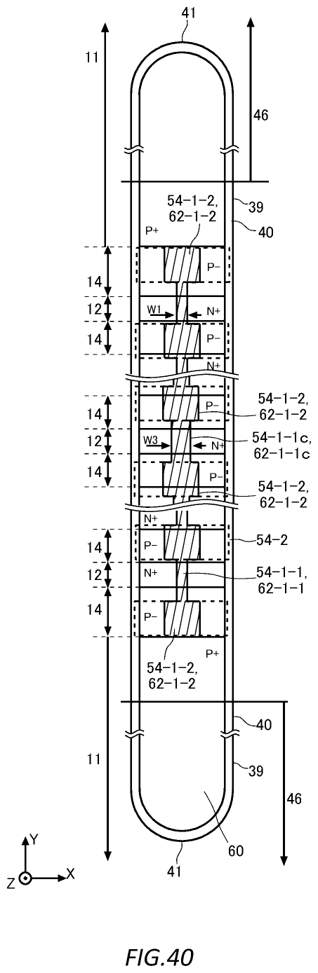

FIG. 40 shows another exemplary structure of a first segment 54-1-1 of a contact hole 54-1 and a first segment 62-1-1 of a plug metal 62-1. One mesa portion 60 is shown in FIG. 40, but other mesa portions 60 may have a similar structure. In the examples shown in FIG. 35 to FIG. 39, the plurality of first segments 54-1-1 provided in one mesa portion 60 have the same shape, and the plurality of first segments 62-1-1 have the same shape. In the present example, in one mesa portion 60, a plurality of first segments 54-1-1 with different shapes are provided, and a plurality of first segments 62-1-1 with different shapes are provided.

Among the plurality of first segments 54-1-1 provided in one mesa portion 60, the segment arranged at a center of the mesa portion 60 in the extending direction (the Y axis direction) is referred to as a first segment 54-1-1c. Similarly, among the plurality of first segments 62-1-1 provided in one mesa portion 60, the segment arranged at the center of the mesa portion 60 in the extending direction (the Y axis direction) is referred to as a first segment 62-1-1c. A width W3 of the first segment 54-1-1c may be larger than the width W1 of the first segment 54-1-1 arranged at the end in the Y axis direction. Similarly, the width W3 of the first segment 62-1-1c may be larger than the width W1 of the first segment 62-1-1 arranged at the end in the Y axis direction. This makes it easy to extract holes in the vicinity of the center of the mesa portion 60 where holes easily concentrate.

In the present example, the width of the first segment 54-1-1 and the first segment 62-1-1 at the center of the mesa portion 60 is different from the width of the first segment 54-1-1 and the first segment 62-1-1 at an end portion of the mesa portion 60. In another example, the width of the second segment 54-1-2 and the second segment 62-1-2 at the center of the mesa portion 60 may be larger than the width of the second segment 54-1-2 and the second segment 62-1-2 at the end portion of the mesa portion 60.

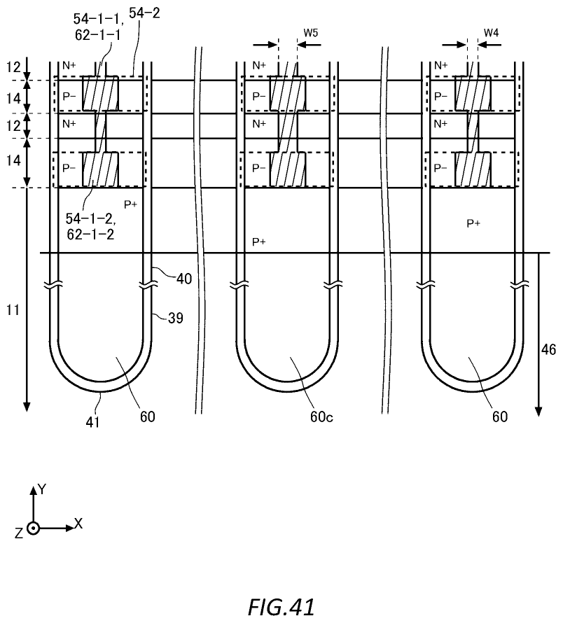

FIG. 41 shows another exemplary structure of the first segment 54-1-1 of the contact hole 54-1 and the first segment 62-1-1 of the plug metal 62-1. FIG. 41 shows a plurality of mesa portions 60 arranged in the X axis direction. Among the plurality of mesa portions 60, the portion arranged at a center in the X axis direction is referred to as a mesa portion 60c.

In the examples shown in FIG. 35 to FIG. 40, the plurality of first segments 54-1-1 provided in the plurality of mesa portions 60 have the same shape, and the plurality of first segments 62-1-1 have the same shape. In the present example, in different mesa portions 60, a plurality of first segments 54-1-1 with different shapes are provided, and a plurality of first segments 62-1-1 with different shapes are provided.

A width W5 of the first segment 54-1-1c in the mesa portion 60c may be larger than a width W4 of the first segment 54-1-1 of the mesa portion 60 arranged at the end in the X axis direction. Similarly, the width W5 of the first segment 62-1-1c in the mesa portion 60c may be larger than the width W4 of the first segment 62-1-1 of the mesa portion 60 arranged at the end in the X axis direction. This makes it easy to extract holes in the vicinity of the center of the semiconductor substrate 10 where holes easily concentrate.

In the present example, the widths of the first segment 54-1-1 and the first segment 62-1-1 are different between the different mesa portions 60. In another example, the width of the second segment 54-1-2 and the second segment 62-1-2 of the mesa portion 60c may be larger than the width of the second segment 54-1-2 and the second segment 62-1-2 at the end portion of the mesa portion 60 arranged at the end in the X axis direction. In addition, intervals in the Y axis direction at which the second segment 54-1-2 and the second segment 62-1-2 are provided may be different between the different mesa portions 60. The interval in the Y axis direction at which the second segment 54-1-2 and the second segment 62-1-2 are provided in the mesa portion 60c may be smaller than the interval in the Y axis direction at which the second segment 54-1-2 and the second segment 62-1-2 are provided in the mesa portion 60 arranged at the end in the X axis direction. Such arrangement also makes it easy to extract holes in the vicinity of the center of the semiconductor substrate 10 where holes easily concentrate.

While the present invention has been described by using the embodiments, the technical scope of the present invention is not limited to the scope described in the above-described embodiments. It is apparent to persons skilled in the art that various alterations or improvements can be added to the above-described embodiments. It is also apparent from the description of the claims that the embodiments added with such alterations or improvements can be included in the technical scope of the present invention.

It should be noted that the operations, procedures, steps, stages, and the like of each processing performed by an apparatus, system, program, and method shown in the claims, specification, or drawings can be performed in any order as long as the order is not indicated by “prior to,” “before,” or the like and as long as the output from a previous processing is not used in a later processing. Even if the operation flow is described using phrases such as “first” or “next” for the sake of convenience in the claims, specification, or drawings, it does not necessarily mean that the process must be performed in this order.

What is claimed is:

1. A semiconductor apparatus having a MOS gate structure, comprising:
a semiconductor substrate;
a first interlayer dielectric film provided above an upper surface of the semiconductor substrate and including a first opening; and
a second interlayer dielectric film stacked on the first interlayer dielectric film and including a second opening overlapping the first opening in a top view, wherein
a width of the first opening in a first direction is different from a width of the second opening in the first direction, at a boundary height between the first interlayer dielectric film and the second interlayer dielectric film.

2. The semiconductor apparatus according to claim 1, wherein
the width of the second opening in the first direction is larger than the width of the first opening in the first direction at the boundary height.

3. The semiconductor apparatus according to claim 2, wherein
at least part of an upper surface of the first interlayer dielectric film is not covered with the second interlayer dielectric film.

4. The semiconductor apparatus according to claim 1, wherein
the width of the second opening in the first direction is smaller than the width of the first opening in the first direction at the boundary height.

5. The semiconductor apparatus according to claim 1, further comprising
a gate trench portion provided from the upper surface of the semiconductor substrate to an inside of the semiconductor substrate, wherein
the gate trench portion includes:
a gate conductive portion provided on the semiconductor substrate; and
a gate dielectric film which insulates the gate conductive portion from the semiconductor substrate, and
the first interlayer dielectric film covers at least part of an upper surface of the gate conductive portion.

6. The semiconductor apparatus according to claim 5, comprising
a plurality of gate trench portions including the gate trench portion, wherein
the plurality of gate trench portions are arrayed in the first direction.

7. The semiconductor apparatus according to claim 6, further comprising
a mesa portion provided between the plurality of gate trench portions, wherein
a thickness of the first interlayer dielectric film is equal to or less than a width of the mesa portion in the first direction.

8. The semiconductor apparatus according to claim 1, further comprising
a first plug metal at least partially provided in the first opening; and
a second plug metal at least partially provided in the second opening.

9. The semiconductor apparatus according to claim 8, further comprising
a barrier metal provided between the first plug metal and the second plug metal and containing titanium.

10. The semiconductor apparatus according to claim 1, wherein
a side wall of the first opening is steeper than a side wall of the second opening.

11. The semiconductor apparatus according to claim 1, wherein
a thickness of the second interlayer dielectric film is larger than a thickness of the first interlayer dielectric film.

12. The semiconductor apparatus according to claim 1, wherein
an interval at which a plurality of first openings including the first opening are arranged in the first direction is different from an interval at which a plurality of second openings including the second opening are arranged in the first direction.

13. The semiconductor apparatus according to claim 12, wherein
at least one of the plurality of first openings is covered with the second interlayer dielectric film.

14. The semiconductor apparatus according to claim 12, wherein
the second openings are discretely provided in a top view.

15. The semiconductor apparatus according to claim 1, further comprising
a plug metal provided in the semiconductor substrate, below the first opening.

16. The semiconductor apparatus according to claim 15, further comprising:
a plurality of gate trench portions provided from the upper surface of the semiconductor substrate to an inside of the semiconductor substrate; and
a mesa portion provided between two of the gate trench portions and extending in a trench extending direction at the upper surface of the semiconductor substrate, wherein
the plug metal includes: a first segment; and a second segment provided side by side with the first segment in the trench extending direction and having a width larger than that of the first segment, and
at least part of the first segment of the plug metal is arranged at a position which does not overlap the second opening.

17. The semiconductor apparatus according to claim 16, wherein
the semiconductor substrate includes a drift region of a first conductivity type,
the mesa portion includes:
an emitter region of the first conductivity type exposed on the upper surface of the semiconductor substrate; and
a region of a second conductivity type exposed on the upper surface of the semiconductor substrate, wherein regions of the second conductivity type including the region of the second conductivity type are alternately arranged with emitter regions including the emitter region in the trench extending direction, wherein
at least part of the second segment of the plug metal overlaps the region of the second conductivity type.

18. A method for manufacturing a semiconductor apparatus having a MOS gate structure, the method comprising:
forming a first interlayer dielectric film above a semiconductor substrate;
forming a first opening in the first interlayer dielectric film;
forming a contact portion in the first opening;
forming a second interlayer dielectric film stacked on the first interlayer dielectric film; and
forming a second opening in the second interlayer dielectric film, wherein
a width of the first opening in a first direction is different from a width of the second opening in the first direction, at a boundary height between the first interlayer dielectric film and the second interlayer dielectric film.

19. The semiconductor apparatus according to claim 2, further comprising
a gate trench portion provided from the upper surface of the semiconductor substrate to an inside of the semiconductor substrate, wherein
the gate trench portion includes:
a gate conductive portion provided on the semiconductor substrate; and
a gate dielectric film which insulates the gate conductive portion from the semiconductor substrate, and
the first interlayer dielectric film covers at least part of an upper surface of the gate conductive portion.

20. The semiconductor apparatus according to claim 3, further comprising
a gate trench portion provided from the upper surface of the semiconductor substrate to an inside of the semiconductor substrate, wherein
the gate trench portion includes:
a gate conductive portion provided on the semiconductor substrate; and
a gate dielectric film which insulates the gate conductive portion from the semiconductor substrate, and
the first interlayer dielectric film covers at least part of an upper surface of the gate conductive portion.
